(19) United States
(12) Patent Application Publication
(10) Pub. No.: US 2005/0124113 A1
(43) Pub. Date: Jun. 9, 2005

(54) Method for fabricating semiconductor device

(75) Inventor: Kenji Yoneda, Kyoto (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD.

(21) Appl. No.: 10/985,883

(22) Filed: Nov. 12, 2004

(30) Foreign Application Priority Data
Nov. 12, 2003 (JP) 2003-382599

(51) Int. Cl. H01L 21/44

(52) U.S. Cl. 438/255; 438/398; 438/665; 438/964

(57) ABSTRACT

In a method for fabricating a semiconductor device, a first electrode made of polycrystalline silicon is subjected to first plasma containing oxygen, thereby forming a silicon oxide film in the surface of the first electrode. Then, the first electrode in which the silicon oxide film has been formed is subjected to second plasma containing nitrogen, thereby changing the silicon oxide film into a silicon oxynitride film. Subsequently, a capacitive insulating film made of a metal oxide is formed on the first electrode in which the silicon oxynitride film has been formed. Thereafter, the capacitive insulating film is subjected to third plasma containing oxygen, thereby supplying oxygen to the capacitive insulating film. Thereafter, thermal processing is performed in an oxidizing atmosphere on the capacitive insulating film to which oxygen has been supplied, and then a second electrode is formed on the capacitive insulating film.

### CROSS-REFERENCE TO RELATED APPLICATION

The disclosure of Japanese Patent Application No. 2003-382599 filed on Nov. 12, 2003 including specification, drawings and claims is incorporated herein by reference in its entirety.

### BACKGROUND OF THE INVENTION

The present invention relates to a method for fabricating a semiconductor device including a capacitor with a metal-insulator-semiconductor (MIS) structure in which metal is used for an upper electrode and semiconductor is used for a lower electrode or with a metal-insulator-metal (MIM) structure in which metal is used for both upper and lower electrodes, and particularly a capacitor constituting a memory cell as a dynamic random access memory (DRAM).

With increase in storage capacitance, a DRAM device needs to have its memory cell and peripheral circuits miniaturized. Accordingly, the area occupied by a capacitor constituting the memory cell is also reduced, resulting in that it becomes important how to secure capacitance for storing charge in each capacitor.

To achieve this, a technique for increasing the surface area of an electrode constituting a capacitor is adopted. Specifically, in the case of an MIS or SIS (semiconductor-insulator-semiconductor) structure, the surface of a lower electrode is made uneven, a hemispherical grain (HSG) state or the like in order to increase the surface area two- or threefold.

For a capacitive insulating film, a high-K material such as tantalum oxide having a higher dielectric constant is used to meet miniaturization demand. However, use of tantalum oxide for a capacitive insulating film has constraints because of its physical properties.

Hereinafter, a structure of a conventional semiconductor device including a capacitor with a MIS structure and a method for fabricating the device will be described with reference to FIGS. 15 through 17.

FIG. 15 shows a cross-sectional structure of a conventional semiconductor device including a capacitor. As shown in FIG. 15, a gate electrode 103 is formed over a semiconductor substrate 101 of silicon with a gate oxide film 102 interposed therebetween, and source/drain regions 104 are formed in parts of the semiconductor substrate 101 to both sides of the gate electrode 103. A first interlayer dielectric film 105 is formed over the semiconductor substrate 101 to cover the gate electrode 103 and the upper surface of the first interlayer dielectric film 105 is planarized. A contact plug 106 is formed in part of the first interlayer dielectric film 105 on one of the source/drain regions 104. A second interlayer dielectric film 107 is formed on the first interlayer dielectric film 105 and the upper surface of the second interlayer dielectric film 107 is planarized. In part of the second interlayer dielectric film 107 on the contact plug 106, an opening in which the contact plug 106 is exposed and which has a diameter greater than that of the contact plug 106 is formed.

A lower electrode 108 of polycrystalline silicon having an uneven surface and heavily doped with phosphorus is formed in the opening of the second interlayer dielectric film 107 to cover the bottom and inner wall of the opening. A capacitive insulating film 109 of tantalum oxide is formed on the lower electrode 108. An upper electrode 110 of titanium nitride is formed on the capacitive insulating film 109.

Now, a method for forming a capacitor of the conventional semiconductor device will be described with reference to partial enlarged views of the capacitor shown in FIGS. 16A through 16C, 17A and 17B.

First, as shown in FIG. 16A, a lower electrode 108 having an uneven surface is subjected to rapid thermal nitridation (RTN) at 800° C. to 900° C. for about 30 seconds to 60 seconds with light applied thereto in an ammonia (NH₃) atmosphere, for example, thereby forming a silicon thermal nitride film 108a in the surface of the lower electrode 108 to a thickness of about 1 nm to about 1.5 nm at the maximum.

Next, as shown in FIG. 16B, through a metal organic chemical vapor deposition process, a capacitive insulating film 109 of tantalum oxide (TaOₓ) with a thickness of about 6 nm to about 14 nm is formed at 400° C. to 500° C. over the lower electrode 108 in which the silicon thermal nitride film 108a has been formed, using tantalum ethoxide (Ta(OC₂H₅)₅), for example, as an organic metal source. In this case, the organic metal source is used as a material for tantalum oxide because an organic metal source is easily handled in semiconductor processing. However, tantalum oxide deposited by using the organic metal source is greatly affected by the surface state of its underlying layer during deposition. For example, in a case where a natural oxide film is formed in part of the surface of the lower electrode 108 as the underlying layer, a delay occurs in the deposition of tantalum oxide on a portion where the natural oxide film is formed, so that a variation occurs in thickness of the tantalum oxide film. To prevent this thickness variation, nitridation (thermal nitridation) is performed to make the surface state of the lower electrode 108 uniform before the capacitive insulating film 109 of tantalum oxide is deposited. Tantalum oxide obtained from an organic metal source at a relatively low temperature of about 400° C. to about 500° C. contains a large amount of organic carbon and the oxygen content of this tantalum oxide is smaller than that in Ta₂O₅, which is the stoichiometric composition of tantalum oxide.

In view of this, as shown in FIG. 16C, oxygen is supplied to the capacitive insulating film 109 in an ozone or ozone plasma atmosphere at 800° C. to 850° C., thereby compensating for oxygen deficiency in tantalum oxide constituting the capacitive insulating film 109 and removing organic carbon. In this case, oxygen is preferably supplied at a temperature as high as possible, but tantalum oxide might be reduced if the temperature is excessively high. Therefore, the upper limit of the temperature is about 850° C.

Then, as shown in FIG. 17A, the capacitive insulating film 109 in an amorphous state immediately after deposition is heated in an oxygen atmosphere at 800° C. to 850° C., thereby crystallizing tantalum oxide constituting the capacitive insulating film 109 (i.e., changing tantalum oxide into a polycrystalline state.) In this manner, the dielectric constant of the capacitive insulating film 109 is restored to the original value and leakage current is suppressed. The oxygen supply and crystallization of tantalum oxide may be performed in one process.

Thereafter, as shown in FIG. 17B an upper electrode 110 of titanium nitride with a thickness of about 50 nm is formed on the crystallized capacitive insulating film 109.

The present inventor found out that thermal nitridation by RTN shown in FIG. 16A and oxygen supply using ozone shown in FIG. 16C in the method for forming the conventional capacitor have the following problems.

First, with the RTN process performed on the surface of the lower electrode 108 of polycrystalline silicon, the silicon thermal nitride film 108a whose thickness is substantially uniform along the surface shape of the lower electrode 108, i.e., conformal to the surface of the lower electrode 108, is formed in the uneven surface of the lower electrode 108, but it is difficult to maintain the stability of the surface state of the silicon thermal nitride film 108a. Specifically, after nitridation by RTN has been performed on the lower electrode 108 and before the capacitive insulating film 109 of tantalum oxide is deposited, the surface of the silicon thermal nitride film 108a becomes unstable so that a partial variation occurs in thickness of the capacitive insulating film 109 during the deposition of the capacitive insulating film 109. Because of this partial thickness variation, leakage current flowing in the capacitor increases or decreases, variation occurs in the capacitance of the capacitor and the reliability thereof deteriorates.

Second, though the thickness of the silicon thermal nitride film 108a formed through thermal nitridation by RTN is an important parameter for controlling leakage current flowing in the capacitor and the reliability of the capacitor, this thickness is allowed to be only in the range from about 1 nm to about 1.5 nm. That is, the thickness of the silicon thermal nitride film 108a as an underlying layer for the capacitive insulating film 109 is an important parameter in determining characteristics of the capacitor but cannot be controlled as designed.

Third, in the removal of organic carbon and the oxygen supply for obtaining a composition closer to the stoichiometric composition after deposition of the capacitive insulating film 109 of tantalum oxide, thermal processing at 725° C. for 60 seconds is sufficient for crystallization of tantalum oxide but needs to be performed at a higher temperature to supply oxygen. However, in recent integrated circuit devices each fabricated by mounting a DRAM circuit and a logic circuit on one chip, there is a contradiction that lower processing temperature, i.e., lower thermal budget, is required in order to maintain operation characteristics of a CMOS device constituting the logic circuit.

Fourth, in the oxygen supply, ozone or oxygen plasma is used as an oxidant so that the entire capacitive insulating film 109 of tantalum oxide is uniformly supplied with oxygen from the top through the bottom. However, ozone is a very active oxidant which oxidizes not only the capacitive insulating film 109 but also the silicon thermal nitride film 108a and its underlying lower electrode 108 of polycrystalline silicon, as shown in FIG. 16C. As a result, a silicon oxide film 108b is formed under the silicon thermal nitride film 108a. That is, the thickness of the silicon oxide film 108b having a dielectric constant lower than that of tantalum oxide is added to the thickness of the capacitive insulating film 109, thus causing the problem of large capacitance reduction in the capacitor.

In the case of using oxygen plasma to supply oxygen to tantalum oxide, the energy for generating the plasma needs to be increased in order to supply oxygen to the entire tantalum oxide. As a result, the tendency of oxygen ions to move in straight lines is accelerated. If the lower electrode 108 has a three-dimensional structure and is made of polycrystalline silicon having an uneven surface, oxygen ions do not reach the uneven surface of the lower electrode 108 in part and, in addition, not only the capacitive insulating film 109 but also an access transistor connected to the capacitor might be damaged by the plasma application.

### SUMMARY OF THE INVENTION

It is therefore an object of the present invention to stabilize the surface state of an interface layer between a capacitive insulating film of a metal oxide and a lower electrode serving as an underlying layer for the capacitive insulating film with the thickness of the interface layer made controllable. It is another object of the present invention to ensure oxygen supply to the metal-oxide capacitive insulating film at low temperature.

In order to achieve this object, according to the present invention, an interface layer between a capacitive insulating film of a metal oxide and a first electrode (lower electrode) serving as an underlying layer for the capacitive insulating film is formed by using plasma with low energy. The metal-oxide capacitive insulating film is supplied with oxygen by using plasma with low energy. Both deposition of the metal-oxide capacitive insulating film and oxygen supply thereto are repeated at least twice until the thickness of the capacitive insulating film reaches a given value.

Specifically, a first method for fabricating a semiconductor device according to the present invention includes the steps of: (a) subjecting a first electrode made of polycrystalline silicon to first plasma containing oxygen, thereby forming a silicon oxide film in the surface of the first electrode; (b) subjecting the first electrode in which the silicon oxide film has been formed to second plasma containing nitrogen, thereby changing the silicon oxide film into a silicon oxynitride film; (c) forming a capacitive insulating film made of a metal oxide on the first electrode in which the silicon oxynitride film has been formed; (d) subjecting the capacitive insulating film to third plasma containing oxygen, thereby supplying oxygen to the capacitive insulating film; (e) performing thermal processing in an oxidizing atmosphere on the capacitive insulating film to which oxygen has been supplied; and (f) forming a second electrode on the capacitive insulating film.

In the first method, in step (a), a silicon oxide film as an interface layer to be an underlying layer for a capacitive insulating film of a metal oxide is formed by using plasma containing oxygen. Accordingly, the thickness of this interface layer is controllable in the range from about 0.5 nm to about 4 nm. That is, the thickness of the interface layer which is an important parameter for controlling leakage current flowing in a capacitor and the reliability of the capacitor is controlled to a desired value. As a result, a capacitor having high capacitance, low leakage characteristic and high reliability is implemented.

In the first method, each of the first, second and third plasma preferably has an electron energy between 0.5 eV and 5 eV, both inclusive, and is preferably generated at a temperature between room temperature and 500° C., both inclusive.

In the first method, each of the first and third plasma is preferably generated from oxygen gas or mixed gas obtained by adding krypton to oxygen.

In the first method, the second plasma is preferably generated from nitrogen gas or mixed gas obtained by adding helium or argon to nitrogen.

In the first method, the silicon oxide film formed in the surface of the first electrode preferably has a thickness between 1 nm and 4 nm, both inclusive.

In the first method, a series of processes in which part of the capacitive insulating film is formed in step (c) and then step (d) is performed is preferably repeated until the thickness of the capacitive insulating film reaches a given value. In this manner, layers are formed separately until the thickness of the capacitive insulating film reaches a given value and oxygen is supplied to every layer. This ensures oxygen supply to layers staked to form the capacitive insulating film. In addition, the energy of oxygen plasma can be reduced, so that it is possible to prevent the capacitive insulating film and others from being damaged by plasma.

In this case, the capacitive insulating film obtained by said series of processes preferably has an initial thickness between 2 nm and 4 nm, both inclusive.

A second method for fabricating a semiconductor device according to the present invention includes the steps of: (a) subjecting a first electrode made of polycrystalline silicon to first plasma containing nitrogen, thereby forming a silicon nitride film in the surface of the first electrode; (b) forming a capacitive insulating film made of a metal oxide on the first electrode in which the silicon nitride film has been formed; (c) subjecting the capacitive insulating film to second plasma containing oxygen, thereby supplying oxygen to the capacitive insulating film; (d) performing thermal processing in an oxidizing atmosphere on the capacitive insulating film to which oxygen has been supplied; and (e) forming a second electrode on the capacitive insulating film.

In the second method, in step (a), a silicon nitride film as an interface layer to be an underlying layer for a capacitive insulating film of a metal oxide is formed by using plasma containing nitrogen. Accordingly, the thickness of this interface layer is controllable in the range from about 0.5 nm to about 4 nm. That is, the thickness of the interface layer which is an important parameter for controlling leakage current flowing in a capacitor and the reliability of the capacitor is controlled to a desired value. As a result, a capacitor having high capacitance, low leakage characteristic and high reliability is implemented.

In the second method, each of the first and second plasma preferably has an electron energy between 0.5 eV and 5 eV, both inclusive, and is preferably generated at a temperature between room temperature and 500° C., both inclusive.

In the second method, the first plasma is preferably generated from nitrogen gas or mixed gas obtained by adding helium or argon to nitrogen.

In the second method, the second plasma is preferably generated from oxygen gas or mixed gas obtained by adding krypton to oxygen.

The second method preferably further includes the step of performing thermal processing on the first electrode in an atmosphere containing nitrogen atoms, thereby forming a silicon thermal nitride film in the surface of the first electrode before step (a) is performed, wherein the silicon nitride film into which the silicon thermal nitride film has been changed is obtained in step (a). Then, the conformality of the silicon nitride film as an interface layer over the first electrode is enhanced.

In the second method, after part of the capacitive insulating film has been formed in step (b), a series of processes for implementing step (c) is preferably repeated until the thickness of the capacitive insulating film reaches a given value. In this manner, layers are formed separately until the thickness of the capacitive insulating film reaches a given value and oxygen is supplied to every layer. This ensures oxygen supply to layers staked to form the capacitive insulating film. In addition, the energy of oxygen plasma can be reduced, so that it is possible to prevent the capacitive insulating film and others from being damaged by plasma.

In this case, the capacitive insulating film obtained by said series of processes preferably has an initial thickness between 2 nm and 4 nm, both inclusive.

A third method for fabricating a semiconductor device according to the present invention includes the steps of: (a) forming an insulating interface layer in the surface of a first electrode made of polycrystalline silicon; (b) forming part of a capacitive insulating film made of a metal oxide on the first electrode in which the interface layer has been formed; (c) subjecting said part of the capacitive insulating film to plasma containing oxygen, thereby supplying oxygen to said part of the capacitive insulating film; (d) repeating steps (b) and (c) as a series of processes until the thickness of the capacitive insulating film reaches a given value, and then performing thermal processing on the capacitive insulating film with said given thickness in an oxidizing atmosphere; and (e) forming a second electrode on the capacitive insulating film.

In the third method, a process in which part of a capacitive insulating film is subjected to plasma containing oxygen so as to supply oxygen to this part is repeated as a series of processes until the thickness of the capacitive insulating film reaches a given value. Accordingly, even if the energy of oxygen plasma is reduced, oxygen is supplied to layers stacked to form the capacitive insulating film without fail. In addition, oxygen plasma with reduced energy does not damage the capacitive insulating film and others.

In the third method, the plasma has preferably an electron energy between 0.5 eV and 5 eV, both inclusive, and preferably is generated at a temperature between room temperature and 500° C., both inclusive.

In the third method, the plasma is preferably generated from oxygen gas or mixed gas obtained by adding krypton to oxygen.

In the third method, in step (a), the first electrode is preferably subjected to plasma containing oxygen with an electron energy between 0.5 eV and 5 eV, both inclusive, at a temperature between room temperature and 500° C., both inclusive, thereby forming the interface layer as a silicon oxide film.

In the third method, in step (a), the first electrode is preferably subjected to plasma containing nitrogen with an electron energy between 0.5 eV and 5 eV, both inclusive, at a temperature between room temperature and 500° C., both inclusive, thereby forming the interface layer as a silicon nitride film.

In the third method, the capacitive insulating film obtained by said series of processes preferably has an initial thickness between 2 m and 4 nm, both inclusive.

In the first through third methods preferably further include the step of making the surface of the first electrode uneven before step (a) is performed.

A fourth method for fabricating a semiconductor device according to the present invention includes the steps of: (a) subjecting a conductive first electrode made of a metal nitride to first plasma containing nitrogen, thereby forming a nitrogen-rich layer in the surface of the first electrode, the nitrogen-rich layer having a nitrogen content greater than that in the other part of the first electrode; (b) forming a capacitive insulating film made of a metal oxide on the first electrode in which the nitrogen-rich layer has been formed; (c) subjecting the capacitive insulating film to second plasma containing oxygen, thereby supplying oxygen to the capacitive insulating film; and (d) forming a second electrode on the capacitive insulating film.

With the fourth method, even in a structure in which a first electrode is made of a conductive metal nitride, a nitrogen-rich layer as an interface layer to be an underlying layer for a capacitive insulating film of a metal oxide is formed by using plasma containing nitrogen, thus stabilizing the surface of the nitrogen-rich layer. Accordingly, the interface layer is not oxidized when the metal-oxide capacitive insulating film is formed. As a result, a capacitor having high capacitance, low leakage characteristic and high reliability is implemented.

In the fourth method, each of the first and second plasma preferably has an electron energy between 0.5 eV and 5 eV, both inclusive, and is preferably generated at a temperature between room temperature and 500° C., both inclusive.

In the fourth method, the first plasma is preferably generated from nitrogen gas or mixed gas obtained by adding helium or argon to nitrogen.

In the fourth method, the second plasma is preferably generated from oxygen gas or mixed gas obtained by adding krypton to oxygen.

In the fourth method, after part of the capacitive insulating film has been formed in step (b), a series of processes for implementing step (c) is preferably repeated until the thickness of the capacitive insulating film reaches a given value. In this manner, layers are formed separately until the thickness of the capacitive insulating film reaches a given value and oxygen is supplied to every layer. This ensures oxygen supply to layers staked to form the capacitive insulating film. In addition, the energy of oxygen plasma can be reduced, so that it is possible to prevent the capacitive insulating film and others from being damaged by plasma.

In the fourth method, the first electrode is preferably made of titanium nitride, tantalum nitride or tungsten nitride.

In the fourth method, the second electrode is preferably made of titanium nitride, tantalum nitride or tungsten nitride.

In the first through fourth methods, the capacitive insulating film preferably contains tantalum oxide or hafnium oxide as a main component.

In the first through fourth methods, the oxidizing atmosphere in the thermal processing performed on the capacitive insulating film preferably contains dinitrogen monoxide.

### BRIEF DESCRIPTION OF THE DRAWINGS

FIG. 1 is a cross-sectional view showing a main portion of a semiconductor device including a capacitor according to a first embodiment of the present invention.

FIGS. 2A through 2C are cross-sectional views showing respective process steps of a method for fabricating the semiconductor device of the first embodiment and showing part of the capacitor in an enlarged manner.

FIGS. 3A through 3C are cross-sectional views showing respective process steps of the method for fabricating the semiconductor device of the first embodiment and showing part of the capacitor in an enlarged manner.

FIG. 4 is a cross-sectional view showing a main portion of a semiconductor device including a capacitor according to a second embodiment of the present invention.

FIGS. 5A through 5C are cross-sectional views showing respective process steps of a method for fabricating the semiconductor device of the second embodiment and showing part of the capacitor in an enlarged manner.

FIGS. 6A and 6B are cross-sectional views showing respective process steps of the method for fabricating the semiconductor device of the second embodiment and showing part of the capacitor in an enlarged manner.

FIG. 7 is a cross-sectional view showing a main portion of a semiconductor device including a capacitor according to a third embodiment of the present invention.

FIGS. 8A through 8D are cross-sectional views showing respective process steps of a method for fabricating the semiconductor device of the third embodiment and showing part of the capacitor in an enlarged manner.

FIGS. 9A through 9C are cross-sectional views showing respective process steps of the method for fabricating the semiconductor device of the third embodiment and showing part of the capacitor in an enlarged manner.

FIG. 10 is a graph showing equivalent oxide thicknesses of capacitive insulating films included in capacitors of semiconductor devices according to the first through third embodiments and a conventional example.

FIG. 11 is a graph showing leakage current in the capacitors of the semiconductor devices according to the first through third embodiments and the conventional example.

FIG. 12 is a graph showing 0.1% dielectric breakdown lifetimes of the capacitors of the semiconductor devices according to the first through third embodiments and the conventional example.

FIG. 13 is a cross-sectional view showing a main portion of a semiconductor device including a capacitor according to a fourth embodiment of the present invention.

FIGS. 14A through 14D are cross-sectional views showing respective process steps of a method for fabricating the semiconductor device of the fourth embodiment and showing part of the capacitor in an enlarged manner.

FIG. 15 is a cross-sectional view showing a main portion of a conventional semiconductor device including a capacitor.

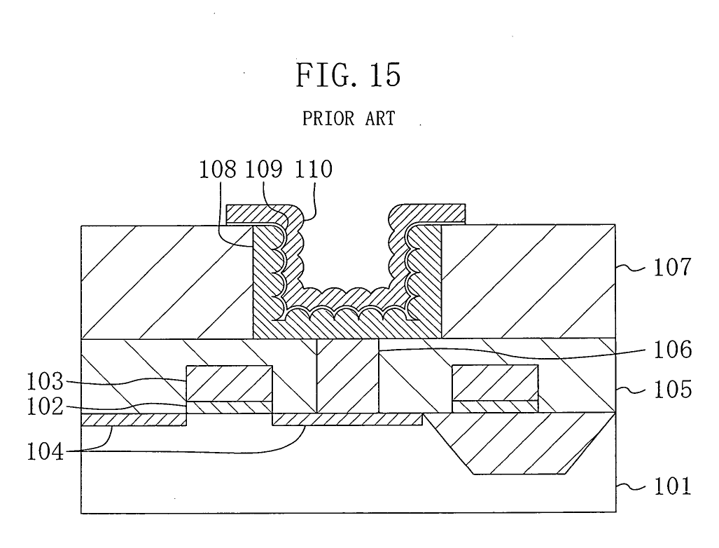

FIGS. 16A through 16C are cross-sectional views showing respective process steps of a method for fabricating the conventional semiconductor device and showing part of the capacitor in an enlarged manner.

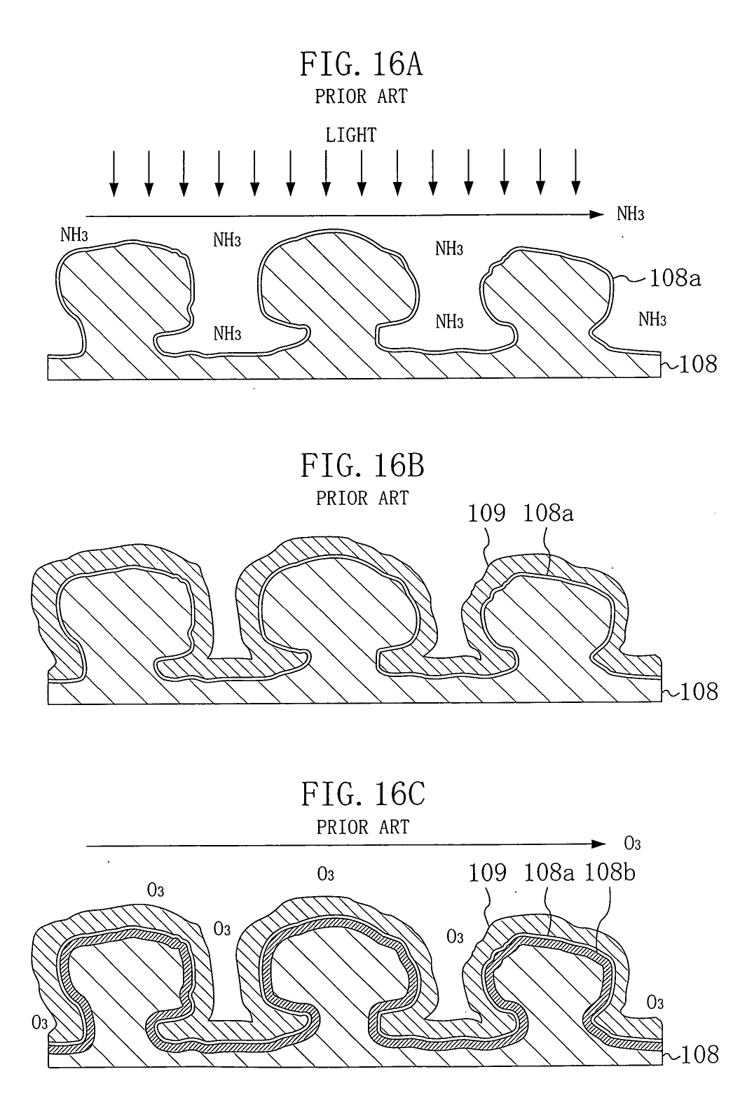

FIGS. 17A and 17B are cross-sectional views showing respective process steps of the method for fabricating the conventional semiconductor device and showing part of the capacitor in an enlarged manner.

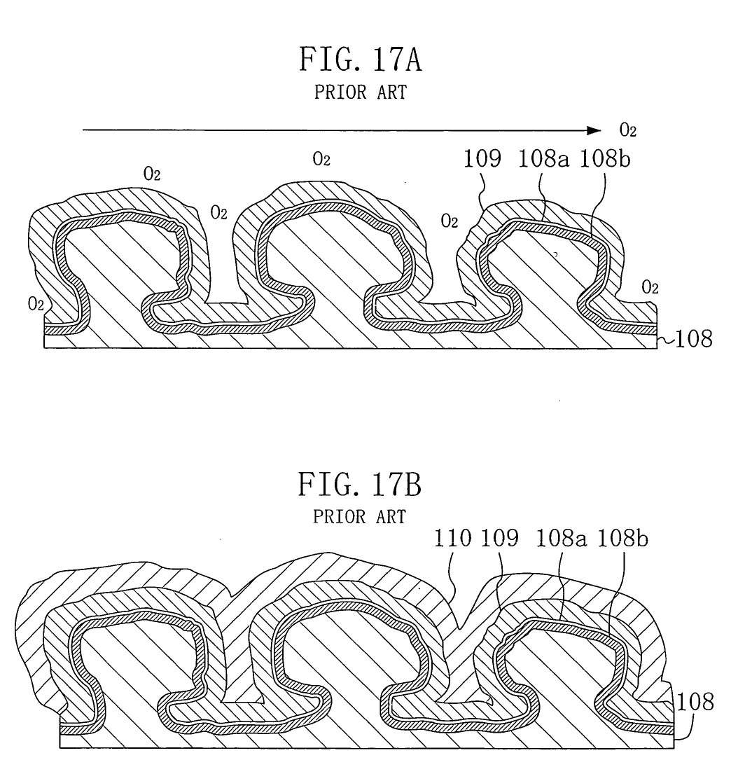

### DESCRIPTION OF THE PREFERRED EMBODIMENTS

### Embodiment 1

A first embodiment of the present invention will be described with reference to the drawings.

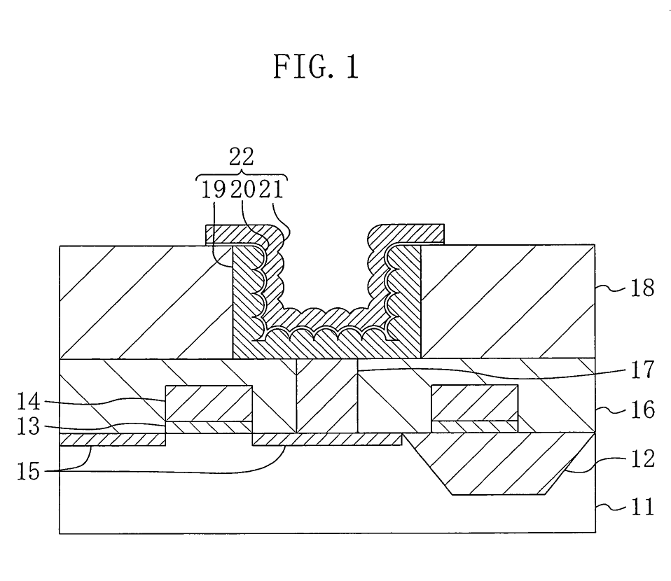

FIG. 1 shows a cross-sectional structure of a main portion of a semiconductor device including a capacitor according to the first embodiment. As shown in FIG. 1, a transistor region is defined by an isolation film 12 in a semiconductor substrate 11 of, for example, silicon (Si). In the transistor region, an access transistor including: a gate electrode 14 formed over the transistor region with a gate insulating film 13 interposed therebetween; and source/drain regions 15 formed in the semiconductor substrate 11 to both sides of the gate electrode 14 is formed.

A first interlayer dielectric film 16 whose upper surface has been planarized is formed over the semiconductor substrate 11 to cover the gate electrode 14. A contact plug 17 of conductive polycrystalline silicon is formed in part of the first interlayer dielectric film 16 on one of the source/drain regions 15.

A second interlayer dielectric film 18 whose upper surface has been planarized is formed on the first interlayer dielectric film 16. In part of the second interlayer dielectric film 18 on the contact plug 17, an opening in which the contact plug 17 is exposed and which has a diameter greater than that of the contact plug 17 is formed.

A lower electrode 19 of polycrystalline silicon having an uneven surface and heavily doped with phosphorus in a concentration of about 5×10²⁰/cm³ is formed in the opening of the second interlayer dielectric film 18 to cover the bottom and inner wall of the opening. A capacitive insulating film 20 of tantalum oxide (TaOₓ) is formed on the lower electrode 19. An upper electrode 21 of titanium nitride (TiN) is formed on the capacitive insulating film 20. In this manner, a MIS capacitor 22 including: the lower electrode 19 connected to the access transistor and having an uneven surface whose area is about 2.5 times as large as that of a flat surface; the capacitive insulating film 20 of a metal oxide; and the upper electrode 21 of a conductive metal nitride is formed.

Instead of tantalum oxide, hafnium oxide may be used for the capacitive insulating film 20. In stead of titanium nitride, tantalum nitride or tungsten nitride may be used for the upper electrode 21.

Hereinafter, a method for forming the capacitor of the semiconductor device thus configured will be described with reference to drawings.

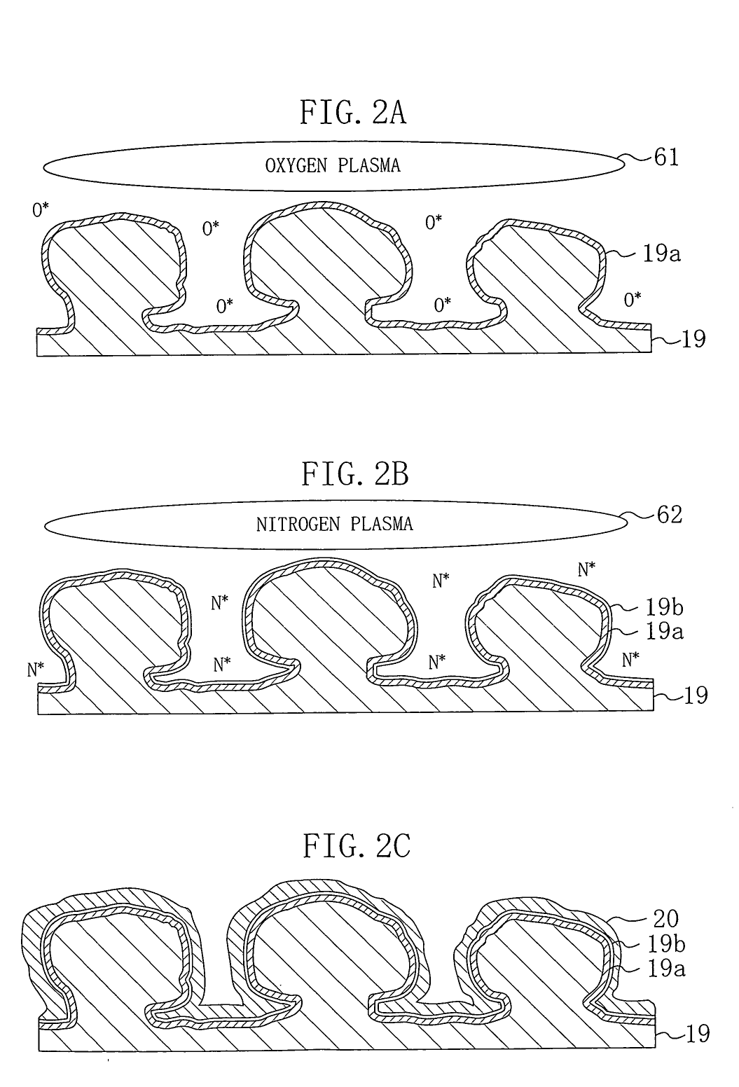

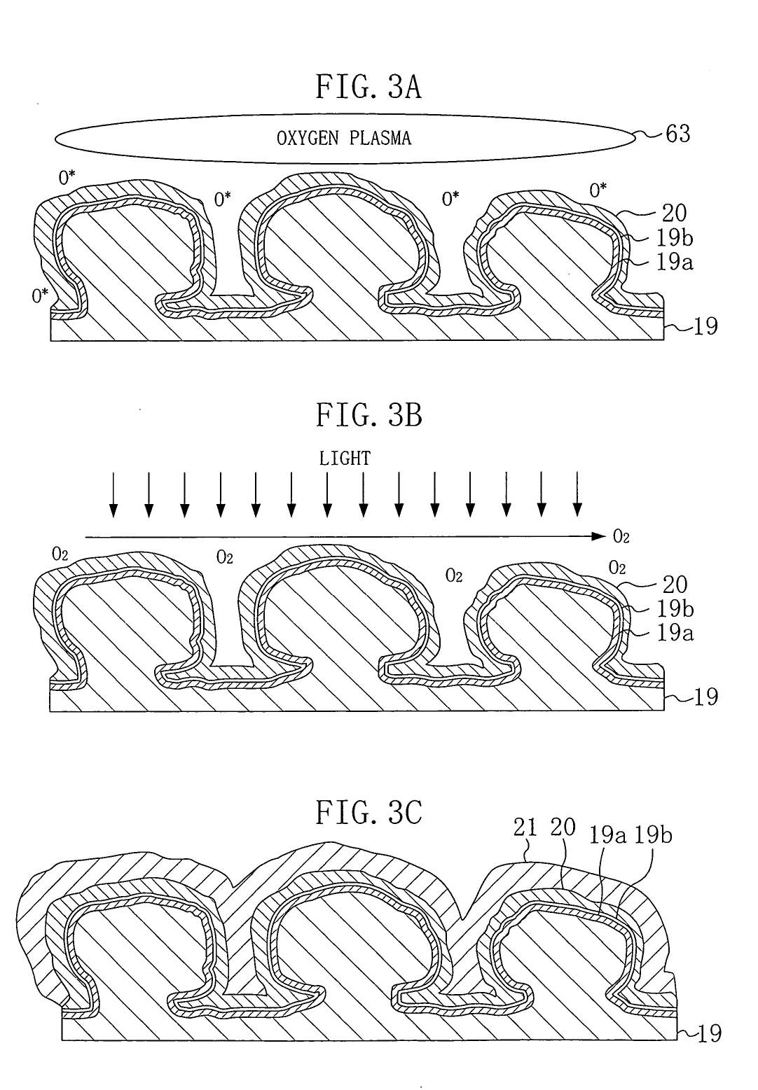

FIGS. 2A through 2C and 3A through 3C show a method for forming the capacitor of the semiconductor device according to the first embodiment. In the drawings, parts of the cross-sectional structures of the capacitor in respective process steps are shown in an enlarged manner.

First, a lower electrode 19 of polycrystalline silicon is deposited by a low pressure chemical vapor deposition (LP-CVD) process over the bottom and inner wall of an opening formed in the second interlayer dielectric film 18. Thereafter, the lower electrode 19 is subjected to low pressure such that migration of silicon atoms occurs on the surface of the lower electrode 19 to form a large number of silicon crystal grains, thereby making the surface of the lower electrode 19 uneven. Subsequently, a natural oxide film formed on the surface of the lower electrode 19 is removed with a hydrofluoric acid solution.

Next, as shown in FIG. 2A, oxygen plasma 61 whose electron energy is as low as about 1.5 eV is generated with the semiconductor substrate 11 heated at about 400° C. Then, the uneven surface of the lower electrode 19 is subjected for 20 seconds to oxygen radicals O* generated from the oxygen plasma 61. In this case, the oxygen plasma 61 is generated with a magnetron at an oxygen-gas flow rate of about 400 m/min (0° C., 1 atm), a pressure of about 10 Pa, and an output (power) of about 400 W. In this manner a silicon oxide film 19a with a thickness of about 2 nm is formed in the surface of the lower electrode 19.

It is generally assumed that formation of a thermal oxide film with a uniform thickness and uniform quality on the surface of polycrystalline silicon, especially heavily-doped polycrystalline silicon, is difficult. This is because polycrystalline silicon has various crystal orientations and, in addition, oxidation is accelerated by an impurity contained in high concentration. Accordingly, it is extremely difficult to form a uniform oxide film in the surface of heavily-doped polycrystalline silicon by thermal oxidation.

On the other hand, in the first embodiment, oxygen radicals O* generated from the oxygen plasma 61 have a low energy of 1.5 eV as described above. This energy is a constraint on the depth at which the oxygen radicals enter in the lower electrode 19. With the plasma output and energy adopted in this embodiment, the maximum thickness of the silicon oxide film is about 4 nm. The thickness of the silicon oxide film cannot be larger than this maximum thickness even if the oxidation period is extended.

Because of the low-energy oxygen plasma 61, the thicknesses of oxide films formed on single crystal silicon and polycrystalline silicon, respectively, are determined substantially only by the electron energy of oxygen radicals O* and are substantially equal to each other. Accordingly, the thickness of the oxide film formed on polycrystalline silicon is not necessarily directly observed with a transmission electron microscope (TEM) or the like. To know the thickness of this film, it is sufficient to measure the thickness of an oxide film formed in the surface of single crystal silicon with optical thickness measurement apparatus such as an ellipsometer.

Oxygen radicals and oxygen ions are generally generated from oxygen plasma 61. Out of these substances, if ions have high energy, these ions have directivity and thus are not likely to reach gaps between crystal grains of polycrystalline silicon in the uneven surface. That is, oxidation occurs only in a portion facing the direction in which oxygen ions are applied but does not occur in a shade portion not facing the direction of the oxygen ion application.

On the other hand, out of substances generated from oxygen plasma 61 with a low energy of 1.5 eV used in this embodiment, oxygen radicals O* contribute to oxidation and are electrically neutral. These oxygen radicals O* readily reach gaps between crystal grains. The oxygen radicals O* which have reached the surfaces of crystal grains in the lower electrode 19 also reach the shade portion behind crystal grains by migration along the surfaces of the crystal grains in the lower electrode 19. As a result, oxidation is performed uniformly even in gaps between crystal grains in the lower electrode 19.

In this manner, the low-energy oxygen plasma 61 greatly contributes to uniform oxidation of the entire uneven surface of the lower electrode 19 having a complex surface shape. Suppose the oxygen plasma 61 has a high electron energy of, for example, several tens of eV. Then, such oxygen plasma with high electron energy is dominated by properties of ions, so that oxidation proceeds in different directions at different speeds.

A plasma generator for generating the low-energy oxygen plasma 61 is not limited to a magnetron, and may be any plasma generator equipped with a plasma source with high plasma density (>1×10¹⁰/cm²) and low energy (0.5 eV to 5 eV) such as inductively coupled plasma, surface-wave plasma or helicon-wave plasma.

The temperature at which the semiconductor substrate 11 is subjected to the oxygen plasma 61 is preferably in the range from room temperature to about 500° C. The substrate temperature hardly affects the oxidation speed but is preferably set at about 400° C. in order to adjust the coupling state of the silicon oxide film 19a caused by oxygen plasma 61 and to promote surface migration of oxygen radicals O* which have reached the surface of the lower electrode 19.

Next, as shown in FIG. 2B, in the chamber in which the oxygen plasma 61 has been generated or another changer to which the semiconductor substrate 11 has been transferred, nitrogen plasma 62 with an electron energy of about 1 eV is generated by using a magnetron at a substrate temperature of 400° C., an output of about 250 W, a nitrogen-gas flow rate of about 500 ml/min (0° C./1 atm) and a pressure of about 30 Pa. Then, the lower electrode 19 is subjected to the nitrogen plasma 62 for 20 seconds. In this manner, at least the surface and its neighboring part of the silicon oxide film 19a formed in the surface of the lower electrode 19 are changed into a silicon nitride film 19b. At this time, the electron energy of nitrogen radicals N* is as low as about 1 eV, and nitridation proceeds more quickly in the surface of the silicon oxide film 19a than in the other part. Accordingly, nitridation less proceeds in part of the silicon oxide film 19a at the interface between the silicon oxide film 19a and the lower electrode 19. At this time, the peak concentration of nitrogen near the surface of the silicon oxide film 19a is about 10 atm %. In this plasma nitridation, nitrogen radicals N* with low energy are generated as in the plasma oxidation. Accordingly, the silicon nitride film 19b is formed uniformly even in gaps between silicon crystal grains in the uneven surface of the lower electrode 19. The silicon oxide film 19a can be assumed to constitute a silicon oxinitride film together with the silicon nitride film 19b formed on the surface and its neighboring part of the silicon oxide film 19a.

Then, as shown in FIG. 2C, over the lower electrode 19 in which the silicon oxide film 19a and the silicon nitride film 19b have been formed, a capacitive insulating film 20 of tantalum oxide (TaOₓ) is deposited to a thickness of about 10 nm, by a metal organic chemical vapor deposition (MOCVD) process at a temperature of about 470° C. and a pressure of about 30 Pa with tantalum ethoxide (Ta(OC₂H₅)₅) as a tantalum source and oxygen (O₂) mixed. As described above, the deposition delay time (incubation time) before the deposition of tantalum oxide by the MOCVD process starts varies depending on the surface state of its underlying layer. Therefore, uniformization of the surface state contributes directly to improvement of uniformity in thickness. For example, the incubation time in a case where tantalum oxide grows on silicon oxide serving as an underlying layer is long whereas the incubation time in a case where tantalum oxide grows on silicon or silicon nitride on which no natural oxide film is formed is short. That is, even if tantalum oxide is deposited on both an underlying layer of silicon oxide (including a natural oxide film) and an underlying layer of silicon nitride for the same period, the thickness of tantalum oxide on silicon oxide is smaller than that on silicon nitride. For example, if the thickness of a natural oxide film varies within the surface of a silicon wafer, the thickness of tantalum oxide deposited thereon also varies greatly. In particular, a natural oxide film is formed nonuniformly at high speed on heavily-doped polycrystalline silicon. Even if the natural oxide film formed on polycrystalline silicon is removed with diluted hydrofluoric acid, another nonuniform natural oxide film is formed immediately.

In the first embodiment, the surface state of the lower electrode 19 of polycrystalline silicon is uniformized through plasma oxidation and subsequent plasma nitridation, so that incubation time for the capacitive insulating film 20 of tantalum oxide is reduced.

Thereafter, as shown in FIG. 3A, oxygen plasma 63 with an electron energy of about 3 eV is generated at a substrate temperature of 400° C., a magnetron output of about 600 W, an oxygen-gas flow rate of about 500 ml/min (0° C., 1 atm) and a pressure of about 10 Pa. Then, the capacitive insulating film 20 is subjected to the oxygen plasma 63 for 80 seconds. In this manner, oxygen is supplied to tantalum oxide constituting the capacitive insulating film 20 so as to compensate for oxygen deficiency in this tantalum oxide and, in addition, organic carbon contained in the tantalum oxide is removed. In this case, the electron energy is relatively high, i.e., 3 eV. This is because the oxygen plasma 63 needs to be distributed throughout the capacitive insulating film 20 with a thickness of 10 nm and to reach gaps between silicon crystal grains in the lower electrode 19. This plasma oxidation performed for the second time is greater than the plasma oxidation performed for the first time, and allows oxidation of a metal oxide with a thickness of about 4 nm or less. With this second plasma oxidation, oxygen is sufficiently supplied to tantalum oxide, thus reducing leakage current in the capacitive insulating film 20 and increasing the dielectric constant of the capacitive insulating film 20. However, of course, oxygen supply is further promoted in the surface of the capacitive insulating film 20 and, though oxygen is also supplied to the bottom of the capacitive insulating film 20, the amount of oxygen supplied the bottom is smaller than that supplied to the surface.

The oxygen plasma 61 and 63 is preferably generated using oxygen (O₂) gas or mixed gas obtained by adding krypton (Kr) to oxygen (O₂). The nitrogen plasma 62 is preferably generated by using nitrogen (N₂) gas or mixed gas obtained by adding helium (He) or argon (Ar) to nitrogen (N₂).

Subsequently, as shown in FIG. 3B, with rapid thermal processing (RTP) apparatus, thermal processing is performed for 90 seconds on the capacitive insulating film 20 subjected to oxygen supply, with light applied thereto at about 800° C. in an oxygen atmosphere, thereby changing tantalum oxide, which is amorphous immediately after deposition, into a polycrystalline state. In this manner, tantalum oxide constituting the capacitive insulating film 20 is crystallized, resulting in that the value of the dielectric constant of the tantalum oxide is restored and leakage current is reduced. It should be noted that tantalum oxide is crystallized by thermal processing performed at 725° C. for about 3 minutes. Therefore, it is sufficient that thermal processing is performed for a short time at a temperature of 725° C. or higher or performed for a long time at a temperature lower than 725° C.

With this rapid thermal processing, tantalum oxide constituting the capacitive insulating film 20 is changed into a polycrystalline state. In addition, oxygen is supplied again from the surface of the tantalum oxide so that oxygen reaches the surface of the lower electrode 19 through the entire capacitive insulating film 20 and its underlying silicon nitride film 19b and silicon oxide film 19a. Accordingly, as the temperature of the rapid thermal processing increases or the period of the process becomes longer, a larger amount of oxygen is supplied to the capacitive insulating film 20, thus improving properties of the capacitive insulating film 20. However, even polycrystalline silicon constituting the lower electrode 19 is oxidized so that the thickness of the silicon oxide film 19a increases, resulting in reduction of substantial dielectric constant of the capacitive insulating film 20.

In addition, as the temperature of the rapid thermal processing increases or the period of the process becomes longer, the thermal budget for a capacitor in the process is more likely to exceed a predetermined value. Therefore, in the first embodiment, the thermal processing is performed at 800° C. for 90 seconds.

Then, as shown in FIG. 3C, an upper electrode 21 of titanium nitride is deposited by a CVD process to a thickness of about 30 nm over the capacitive insulating film 20 at about 630° C. using titanium tetrachloride (TiCl₄) and ammonia (NH₃) as raw materials. The thickness of the upper electrode 21 is an item of the design rule and is preferably as small as possible within the range determined by the design rule. This is because a titanium nitride film has extremely strong film stress and this stress has unfavorable effects on electrical properties of the capacitive insulating film 20. In addition, if the thickness of the titanium nitride film exceeds 60 nm, cracks are caused by the stress of the film itself. When these cracks reach the capacitive insulating film 20, an electrical problem occurs. On the other hand, as the thickness of the titanium nitride film decreases, the stress of the film itself decreases but the resistance thereof increases. Therefore, in view of the tradeoff between stress and resistance, the thickness of the upper electrode 21 of titanium nitride is preferably in the range from about 20 nm to about 40 nm.

The temperature for deposition of titanium nitride is also an item of the design rule and needs to be set so as to obtain lower stress, lower resistance and a smaller amount of chlorine contained in the film.

As described above, in the first embodiment, an interface layer serving as an underlying film for the capacitive insulating film 20 of a metal oxide is constituted by the silicon oxide film 19a whose thickness is controllable by using oxygen plasma 61 with low electron energy and the silicon nitride film 19b which is formed in the surface of the silicon oxide film 19a, i.e., in the face of the silicon oxide film 19a in contact with the capacitive insulating film 20, by using nitrogen plasma 62 with low electron energy and which has a uniform surface state. This interface layer suppresses entering of electrons from the lower electrode 19 serving as a storage node toward the capacitive insulating film 20, thus ensuring suppression of leakage current in the capacitive insulating film 20 in a case where a positive voltage is applied to the upper electrode 21 serving as a cell plate.

In addition, in the first embodiment, the silicon oxide film 19a and the silicon nitride film 19b (i.e., the silicon oxynitride film) together serving as an interface layer between the lower electrode 19 and the capacitive insulating film 20 are formed by a combination of plasma oxidation using oxygen plasma 61 and plasma nitridation using oxygen plasma 61. Therefore, the thickness of the silicon oxide film 19a serving as a potential barrier in injecting electrons into the capacitive insulating film 20 can be arbitrarily selected. On the other hand, nitridation is performed only on the surface of the silicon oxide film 19a independently of the thickness of the silicon oxide film 19a. Accordingly, leakage current is controlled easily as intended by controlling the thickness of the silicon oxide film 19a formed by plasma oxidation. In addition, the surface of the silicon oxide film 19a deposited previous to the silicon nitride film 19b is always maintained in the same nitridation state by plasma nitridation. Accordingly, even if the thickness of the silicon oxide film 19a is changed, the incubation time before the deposition of the capacitive insulating film 20 is not changed, so that the thickness of the capacitive insulating film 20 is always constant.

With the plasma oxidation and plasma nitridation both having low energy, substantially the same advantages are obtained in a wide temperature range from room temperature to about 500° C. In addition, the depths of oxidation and nitridation are controlled by adjusting the electron energy of plasma, so that even for a capacitor having an electrode structure susceptible to oxidation, surface nitridation of the lower electrode 19 and oxygen supply to the capacitive insulating film 20 made of a metal oxide are performed without loss of the function of the electrode. As a result, if the capacitor 22 of the first embodiment is applied to a DRAM device, it is possible to further promote increase in integration density and miniaturization of the DRAM device.

### Embodiment 2

Hereinafter, a second embodiment of the present invention will be described with reference to the drawings.

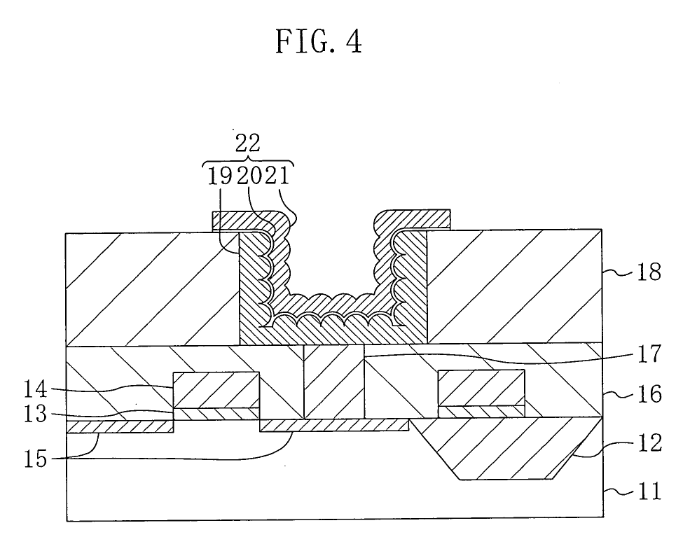

FIG. 4 shows a cross-sectional structure of a main portion of a semiconductor device including a capacitor according to the second embodiment. In FIG. 4, components also shown in FIG. 1 are denoted by the same reference numerals, and the description thereof will be omitted.

The second embodiment is different from the first embodiment in the structure of an interface layer between the lower electrode 19 and the capacitive insulating film 20. Therefore, a method for forming a capacitor 22 will be hereinafter described.

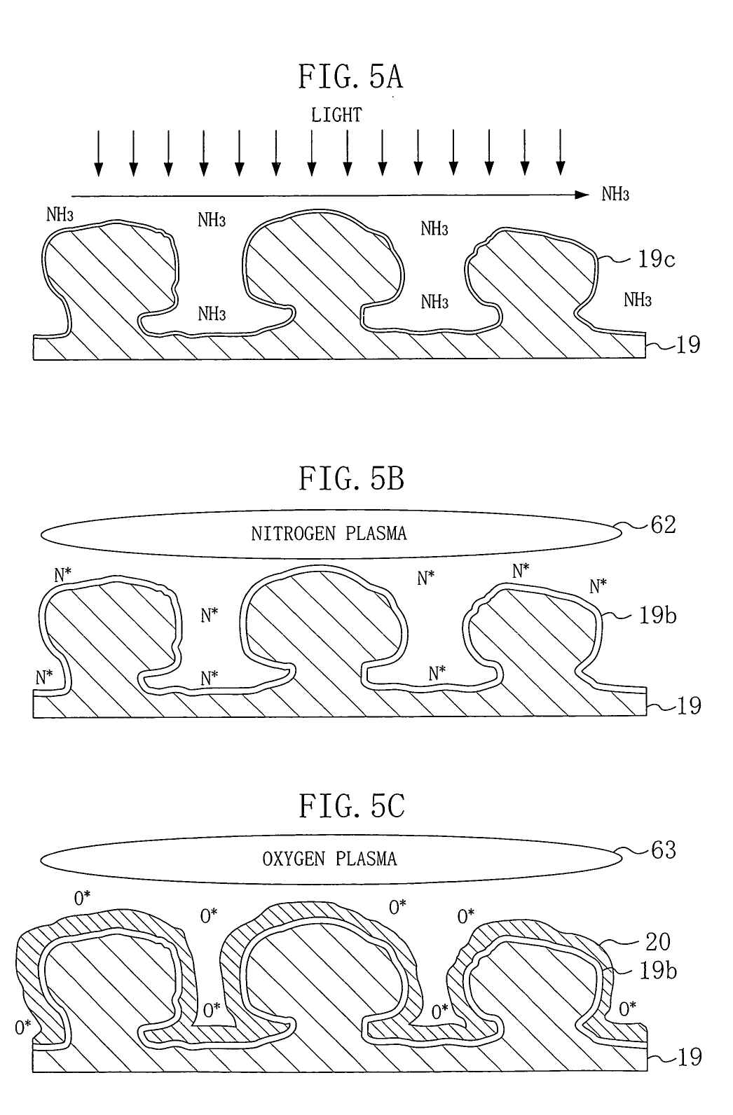

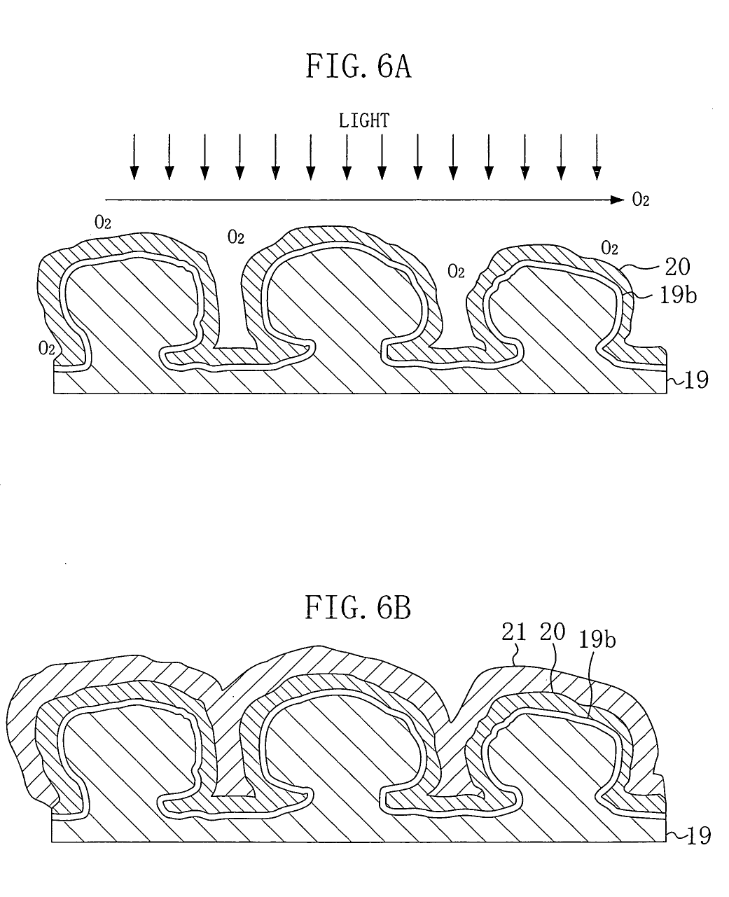

FIGS. 5A through 5C and 6A and 6B show a method for forming the capacitor of the semiconductor device according to the second embodiment. In the drawings, parts of the cross-sectional structures of the capacitor in respective process steps are shown in an enlarged manner.

First, a lower electrode 19 of polycrystalline silicon is deposited by an LP-CVD process over the bottom and inner wall of an opening formed in a second interlayer dielectric film 18. Thereafter, the lower electrode 19 is subjected to high pressure such that migration of silicon atoms occurs on the surface of the lower electrode 19 to form a large number of silicon crystal grains, thereby making the surface of the lower electrode 19 uneven. Subsequently, a natural oxide film formed on the surface of the lower electrode 19 is removed with a hydrofluoric acid solution.

Next, as shown in FIG. 5A, with rapid thermal processing (RTP) apparatus, the lower electrode 19 is subjected to thermal processing at about 600° C. for 60 seconds in an ammonia (NH₃) atmosphere with light applied thereto. In this manner, a silicon thermal nitride film 19c with a thickness of about 1.2 nm is formed in the surface of the lower electrode 19 by thermal nitridation. Instead of ammonia, nitrogen monoxide (NO) may be used for the atmosphere. In such a case, the temperature and time of the thermal processing need to be adjusted in accordance with the thickness of the silicon thermal nitride film 19c to be formed.

Then, as shown in FIG. 5B, nitrogen plasma 62 with an electron energy of about 1 eV is generated by using a magnetron at a substrate temperature of 400° C., an output of about 250 W, a nitrogen-gas flow rate of about 500 ml/min (0° C./1 atm) and a pressure of about 30 Pa. Then, the lower electrode 19 is subjected to the nitrogen plasma 62 for 20 seconds. In this manner, the silicon thermal nitride film 19c which has been formed in the lower electrode 19 by using ammonia and whose surface state is unstable is changed into a silicon nitride film 19b whose surface state is stable and whose thickness is increased to about 2 nm.

To generate nitrogen plasma 62 with low energy, a magnetron is not necessarily used. It is sufficient to use a plasma source with high plasma density (>1×10¹⁰/cm²) and low energy (0.5 eV to 5 eV) such as inductively coupled plasma, surface-wave plasma or helicon-wave plasma.

Then, as shown in FIG. 5C, over the lower electrode 19 in which the silicon nitride film 19b has been formed, a capacitive insulating film 20 of tantalum oxide (TaOₓ) is deposited to a thickness of about 8 nm to about 10 nm by a MOCVD process at a temperature of about 470° C. and a pressure of about 30 Pa with tantalum ethoxide (Ta(OC₂H₅)₅) as a tantalum source and oxygen (O₂) mixed. Since nitridation is performed uniformly throughout the silicon nitride film 19b formed in the surface of the lower electrode 19 and serving as an underlying layer for the capacitive insulating film 20, incubation time does not vary locally, so that the capacitive insulating film 20 formed on the lower electrode 19 has a uniform thickness. Subsequently, oxygen plasma 63 with an electron energy of about 3 eV is generated at a substrate temperature of about 400° C., a magnetron output of about 600 W, an oxygen-gas flow rate of about 500 ml/min (0° C./1 atm) and a pressure of about 10 Pa. Then, the capacitive insulating film 20 is subjected to the oxygen plasma 63 for 80 seconds. In this manner, oxygen is supplied to tantalum oxide constituting the capacitive insulating film 20 to compensate for oxygen deficiency and organic carbon contained in this tantalum oxide is removed. In this case, electron energy is relatively high, i.e., 3 eV, and this energy value is enough to allow oxygen plasma to reach gaps between silicon crystal grains in the lower electrode 19 as described above.

Thereafter, as shown in FIG. 6A, with rapid thermal processing (RTP) apparatus, the capacitive insulating film 20 after oxygen supply is subjected to thermal processing at about 800° C. for 90 seconds in an oxygen atmosphere with light applied thereto. In this manner, tantalum oxide, which is amorphous immediately after deposition, is changed into a polycrystalline state. In this manner, tantalum oxide constituting the capacitive insulating film 20 is crystallized, resulting in that the value of the dielectric constant of the tantalum oxide is restored and leakage current is reduced.

The nitrogen plasma 62 is preferably generated using nitrogen (N₂) gas or mixed gas obtained by adding helium (He) or argon (Ar) to nitrogen (N₂). The oxygen plasma 63 is preferably generated using oxygen (O₂) gas or mixed gas obtained by adding krypton (Kr) to oxygen (O₂).

Then, as shown in FIG. 6B, an upper electrode 21 of titanium nitride is deposited by a CVD process to a thickness of about 30 nm over the capacitive insulating film 20 at about 630° C. using titanium tetrachloride (TiCl₄) and ammonia (NH₃) as raw materials.

As described above, unlike the first embodiment, the underlying layer (interface layer) under the capacitive insulating film 20 of tantalum oxide is made exclusively of the silicon nitride film 19b and does not include the silicon oxide film 19a in the second embodiment. The silicon oxide film 19a in the first embodiment is used for controlling leakage current in the capacitive insulating film 20. Accordingly, the silicon thermal nitride film 19c may be used as an underlying layer instead of the silicon oxide film 19a.

In the case where the silicon thermal nitride film 19c is used as an underlying layer, it is difficult to form the silicon thermal nitride film 19c as thick as the silicon oxide film 19a. Accordingly, the range in which leakage current is suppressed by controlling the thickness is limited. In addition, the function of the silicon thermal nitride film 19c as a potential barrier against electron injection is lower than that of the silicon oxide film 19a.

However, the silicon nitride film 19b of the second embodiment sufficiently reduces leakage current in the capacitive insulating film 20 and also sufficiently stabilizes the surface state thereof before the deposition of the capacitive insulating film 20. Accordingly, though the leakage current is not adjusted within a relatively wide range, it is possible to form tantalum oxide having a high dielectric constant with a relatively small amount of leakage current.

In particular, in the second embodiment, the silicon oxide film 19a having a low dielectric constant is not provided immediately under the capacitive insulating film 20, and the silicon nitride film 19b having a dielectric constant higher than that of silicon oxide is provided instead. Accordingly, the capacitance value of the capacitor 22 itself is larger than that in the first embodiment.

In the second embodiment, thermal nitridation by rapid thermal nitridation (RTN) shown in FIG. 5A and plasma nitridation using nitrogen plasma with low energy shown in FIG. 5B are combined and performed on the lower electrode 19 of polycrystalline silicon having an uneven surface. That is, with these thermal nitridation processes, the very conformal silicon thermal nitride film 19c is formed even if its underlying layer has a complex surface shape.

On the other hand, plasma nitridation enables conformal nitridation of the surface with a complex shape by using nitrogen radicals with low energy. However, a nitride film obtained by plasma nitridation is less perfect than that obtained by ideal thermal nitridation. Therefore, a nitride film formed by thermal nitridation exhibits conformality with respect to a complex shape of an electrode.

In view of this, in the second embodiment, after thermal nitridation has been performed, plasma nitridation with low energy is performed, so that the silicon thermal nitride film 19c is changed into the silicon nitride film 19b whose thickness is increased to about 2 nm and whose surface state is stabilized.

In addition, in the second embodiment, even if a portion where nitrogen radicals do not reach occurs in a shade portion of silicon crystal grains in the lower electrode 19 only by plasma nitridation, this portion has been already subjected to thermal nitridation. Accordingly, the portion does not act as a weak spot with respect to leakage current. That is, thermal nitridation and plasma nitridation complement each other. In particular, hydrogen remains on the surface of the nitride film after thermal nitridation performed in an ammonia atmosphere. If the surface is left for a long time as it is, the state of the surface is changed. In the case of using nitrogen monoxide (NO) for a nitridation atmosphere, the resultant nitride film is not perfect because this atmosphere contains oxygen. Accordingly, plasma nitridation is performed after the thermal nitridation so that the surface state of the lower electrode 19 is stabilized. As a result, tantalum oxide is deposited uniformly over the lower electrode 19.

In the second embodiment, plasma oxidation and plasma nitridation both having lower energy than thermal oxidation and thermal nitridation are employed. Such plasma oxidation and plasma nitridation achieve conformality close to that obtained by thermal oxidation and thermal nitridation. On the other hand, plasma processing is a reaction caused by particles having energy, so that if the surface shape of a film to be formed has a three-dimensional structure, plasma oxidation and plasma nitridation are less perfect than thermal oxidation and thermal nitridation.

In the lower electrode 19 with a three-dimensional structure and an uneven surface, a weak spot might occur though this possibility is low. In view of this, in the second embodiment, thermal nitridation which further ensures conformal processing is added. However, even if this thermal nitridation is not performed, a silicon oxide film as in the conventional example is not formed between the silicon nitride film 19b as an interface layer and the lower electrode 19, during oxygen supply to the capacitive insulating film 20 and oxidizing thermal processing for crystallization. Accordingly, the effect of preventing the capacitance value of the capacitor 22 from decreasing is obtained in such a case. Therefore, thermal nitridation is not necessarily performed before plasma nitridation.

On the other hand, in the first embodiment, though thermal oxidation and thermal nitridation are not performed on the lower electrode 19, plasma oxidation and plasma nitridation are performed successively. Therefore, it is considered that weak spots created by these processes complement each other, and thus disappear.

A combination of processes in which thermal oxidation is performed instead of first thermal nitridation and then plasma nitridation is performed unlike the method of the second embodiment, is not applicable. This is because it is difficult to form a uniform thin oxide film on heavily-doped polycrystalline silicon by thermal oxidation, unlike the case of using thermal nitridation, as described above.

### Embodiment 3

Hereinafter, a third embodiment of the present invention will be described with reference to the drawings.

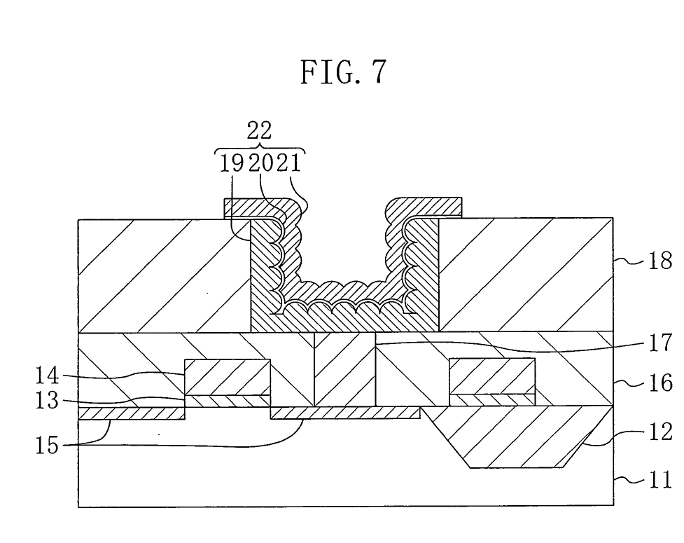

FIG. 7 shows a cross-sectional structure of a main portion of a semiconductor device including a capacitor according to the third embodiment. In FIG. 7, components also shown in FIG. 1 are denoted by the same reference numerals, and the description thereof will be omitted.

The third embodiment is different from the first embodiment in that the capacitive insulating film 20 has a multilayer structure. Therefore, a method for forming a capacitor 22 will be hereinafter described.

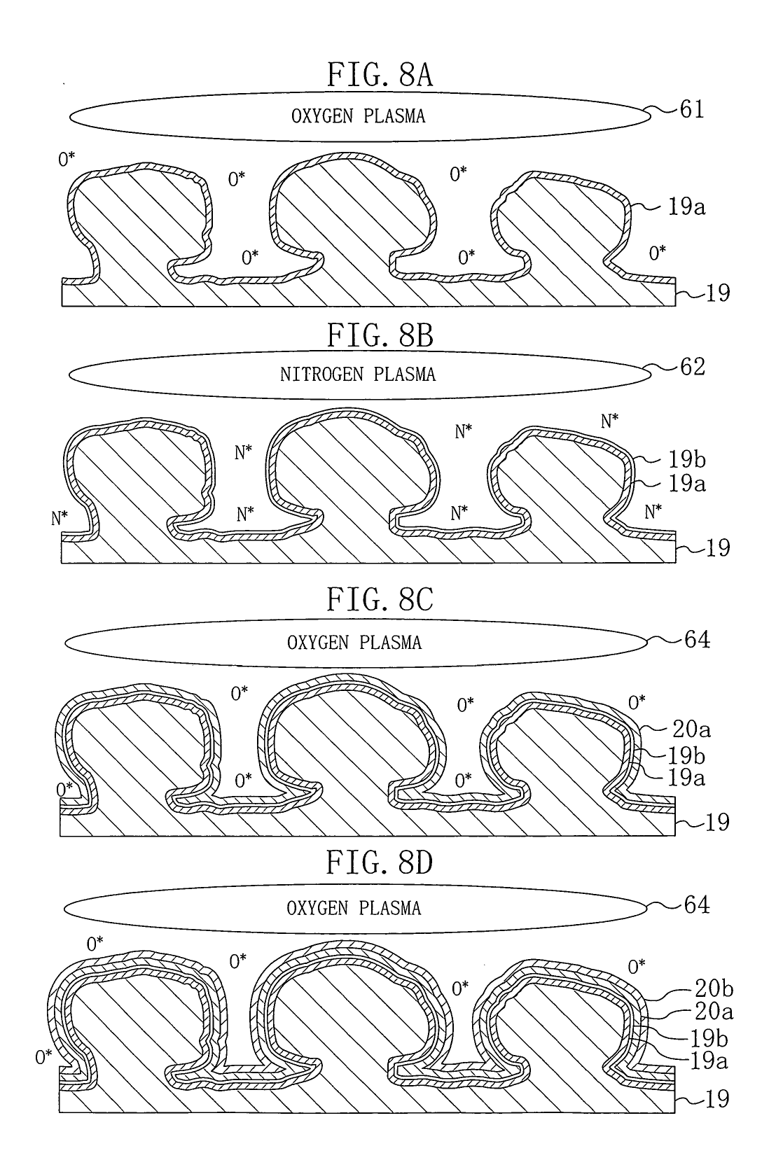

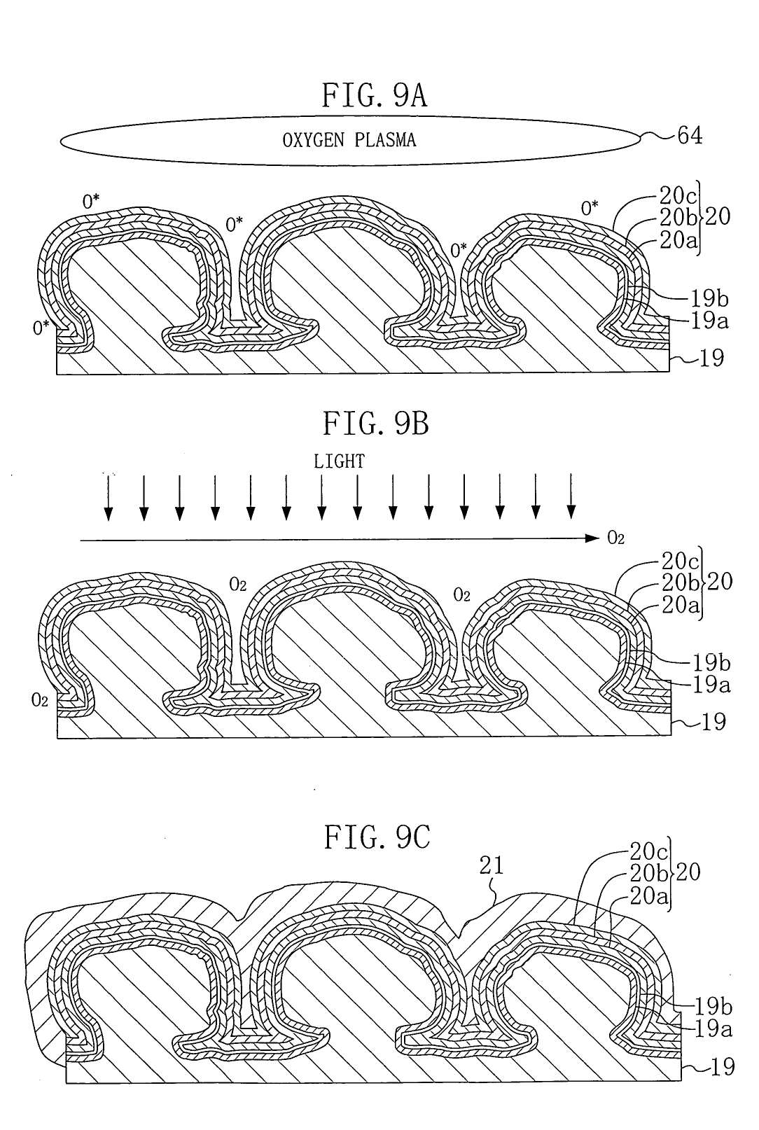

FIGS. 8A through 8D and 9A through 9C show a method for forming the capacitor of the semiconductor device according to the third embodiment. In the drawings, parts of the cross-sectional structures of the capacitor in respective process steps are shown in an enlarged manner.

First, a lower electrode 19 of polycrystalline silicon is deposited by a low pressure chemical vapor deposition (LP-CVD) process over the bottom and inner wall of an opening formed in a second interlayer dielectric film 18. Thereafter, the lower electrode 19 is subjected to high pressure such that migration of silicon atoms occurs on the surface of the lower electrode 19 to form a large number of silicon crystal grains, thereby making the surface of the lower electrode 19 uneven. Subsequently, a natural oxide film formed on the surface of the lower electrode 19 is removed with a hydrofluoric acid solution.

Next, as shown in FIG. 8A, oxygen plasma 61 with a low electron energy of about 1.5 eV is generated with a semiconductor substrate 11 heated at about 400° C. Then, the uneven surface of the lower electrode 19 is subjected for 20 seconds to oxygen radicals O* generated from the oxygen plasma 61. In this case, the oxygen plasma 61 is generated with a magnetron at an oxygen-gas flow rate of about 400 ml/min (0° C., 1 atm), a pressure of about 10 Pa and an output of about 400 W, for example. In this manner, a silicon oxide film 19a with a thickness of about 2 nm is formed in the surface of the lower electrode 19.

Thereafter, as shown in FIG. 8B, in the chamber in which the oxygen plasma 61 has been generated or another chamber to which the semiconductor substrate 11 has been transferred, nitrogen plasma 62 with an electron energy of about 1 eV is generated by using a magnetron at a substrate temperature of 400° C., an output of about 250 W, a nitrogen-gas flow rate of about 500 ml/min (0° C./1 atm) and a pressure of about 30 Pa. Then, the lower electrode 19 is subjected to the nitrogen plasma 62 for 20 seconds. In this manner, at least the surface and its neighboring part of the silicon oxide film 19a formed in the surface of the lower electrode 19 are changed into a silicon nitride film 19b.

Subsequently, as shown in FIG. 8C, a first capacitive insulating film 20a of tantalum oxide (TaOₓ) is formed by a MOCVD process at about 470° C. and a pressure of about 30 Pa with tantalum ethoxide (Ta(OC₂H₅)₅) as a tantalum source and oxygen (O₂) mixed, over the lower electrode 19 in which the silicon oxide film 19a and the silicon nitride film 19b have been formed. Thereafter, oxygen plasma 64 with an electron energy of about 3 eV is generated at a substrate temperature of about 400° C., a magnetron output of about 400 W, an oxygen-gas flow rate of about 25 ml/min (0° C., 1 atm), a krypton (Kr)-gas flow rate of about 375 ml/min (0° C., 1 atm) and a pressure of about 30 Pa. Then, the first capacitive insulating film 20a is subjected to the oxygen plasma 64 for 70 seconds. In this manner, oxygen is supplied to tantalum oxide constituting the first capacitive insulating film 20a to compensate for oxygen deficiency and organic carbon contained in this tantalum oxide is removed. The addition of krypton to the oxygen plasma 64 described above causes a larger amount of oxygen radicals O* to be generated. It should be noted that use of oxygen plasma 64 generated only from oxygen gas to which krypton is not added allows oxygen to be supplied to the first capacitive insulating film 20a but addition of krypton achieves more efficient oxygen supply. Accordingly, this oxygen supply performed for the first time on the first capacitive insulating film 20a allows oxygen to be supplied sufficiently to the first capacitive insulating film 20a with a thickness of 3 nm from its surface to a portion thereof near the interface between the first capacitive insulating film 20a and the silicon nitride film 19b.

Then, as shown in FIG. 8D, a second capacitive insulating film 20b of tantalum oxide (TaOₓ) is deposited by a MOCVD process at 470° C. and a pressure of 30 Pa with tantalum ethoxide (Ta(OC₂H₅)₅) as a tantalum source and oxygen (O₂) mixed, to a thickness of about 3 nm over the first capacitive insulating film 20a. Thereafter, oxygen plasma 64 with an electron energy of about 3 eV is generated at a substrate temperature of 400° C., a magnetron output of about 400 W, an oxygen-gas flow rate of about 25 ml/min (0° C., 1 atm), a krypton (Kr)-gas flow rate of about 375 ml/min (0° C., 1 atm) and a pressure of about 30 Pa. Then, the second capacitive insulating film 20b is subjected to the oxygen plasma 64 for 70 seconds. In this manner, oxygen is supplied to tantalum oxide constituting the second capacitive insulating film 20b to compensate for oxygen deficiency and organic carbon contained in this tantalum oxide is removed. This second oxygen supply performed on the second capacitive insulating film 20b allows a sufficient amount of oxygen to be supplied to the second capacitive insulating film 20b with a thickness of 3 nm from its surface to a portion thereof near the interface between the second capacitive insulating film 20b and the first capacitive insulating film 20a. This is because the thickness of each of the capacitive insulating films 20a and 20b is substantially equal to the depth at which oxygen radicals O* generated from the oxygen plasma 64 reach.

In the third embodiment, the thickness of the capacitive insulating film 20 is designed at 10 nm. Therefore, as shown in FIG. 9A, a third capacitive insulating film 20c of tantalum oxide with a thickness of 4 nm is formed on the second capacitive insulating film 20b. Subsequently, the third capacitive insulating film 20c is subjected to the oxygen plasma 64 for oxygen supply. In this manner, in the third embodiment, the capacitive insulating films 20a, 20b and 20c each having a thickness in the range from 2 nm to 4 nm so as to ensure oxygen supply to each films are stacked to form the capacitive insulating film 20 such that the thickness of the capacitive insulating film 20 reaches a designed value.

The thickness of the first capacitive insulating film 20a in this multilayer structure is preferably equal to or smaller than that of the second capacitive insulating film 20b or each of the subsequent film(s), i.e., the third capacitive insulating film 20c in this embodiment. This is because oxygen is basically unlikely to reach the lowermost first capacitive insulating film 20a by oxygen supply and therefore the thickness of the first capacitive insulating film 20a is set small beforehand so that a sufficient amount of oxygen is supplied. In the third embodiment, the capacitive insulating films 20a, 20b and 20c have thicknesses enough to allow oxygen radicals O* generated by plasma oxidation to enter these films sufficiently. However, in mass-production, a series of processes in which plasma oxidation is repeated to form three or more layers constituting the capacitive insulating film 20 can be inefficient. Accordingly, in such a case that the efficiency of the process is assigned priority, oxygen supply is most important. Therefore, only the thickness of the first capacitive insulating film 20a to which oxygen is not likely to be supplied in subsequent processes may be as small as about 2 nm to about 4 nm and the thickness of the second capacitive insulating film 20b may be relatively large, i.e., may be a value obtained by subtracting the thickness of the first capacitive insulating film 20a from a designed thickness. For example, in the case of forming the capacitive insulating film 20 whose designed thickness is 10 nm, the thickness of the first capacitive insulating film 20a is 3 nm and after plasma oxidation, the second capacitive insulating film 20b is formed to have a thickness of 7 nm. Combinations of thicknesses of the capacitive insulating films 20a and 20b are, of course, not limited to the above combination. For the second capacitive insulating film 20b with a thickness of 7 nm, oxygen is supplied from the surface side thereof by rapid thermal oxidation (RTO), for example, in a subsequent process, so that the leakage current characteristic and the dielectric constant can be maintained. However, to obtain excellent device characteristics of the capacitor 22, the respective capacitive insulating films are preferably stacked in a manner that each of the capacitive insulating films has a thickness which allows oxygen radicals generated by plasma oxidation to sufficiently enter the film.

Then, as shown in FIG. 9B, with rapid thermal processing (RTP) apparatus, thermal processing is performed on the capacitive insulating film 20 at about 800° C. in an oxygen atmosphere for 90 seconds with light applied thereto, thereby changing tantalum oxide, which is amorphous immediately after deposition, into a polycrystalline state.

Thereafter, as shown in FIG. 9C, an upper electrode 21 of titanium nitride is deposited by a CVD process to a thickness of about 30 nm over the capacitive insulating film 20 at about 630° C. using titanium tetrachloride (TiCi₄) and ammonia (NH₃) as raw materials.

Now, physical characteristics of MIS capacitors obtained in the first through third embodiments will be compared. First, the methods for forming the capacitors according to the respective embodiments will be mentioned again. In the first embodiment, the interface layer serving as the underlying layer for the capacitive insulating film 20 between the capacitive insulating film 20 and the lower electrode 19 is constituted by the silicon oxide film 19a formed by using oxygen plasma with low energy and the silicon nitride film 19b formed by using nitrogen plasma with low energy on the surface of the silicon oxide film 19a. In the second embodiment, the interface layer serving as the underlying layer for the capacitive insulating film 20 is formed in a manner that the silicon thermal nitride film 19c is formed by thermal nitridation and then this silicon thermal nitride film 19c is changed into the silicon nitride film 19b by using nitrogen plasma with low energy. In the third embodiment, a structure in which the capacitive insulating film 20 has a multilayer structure including layers each having a thickness enough to allow sufficient oxygen supply is added to the structure of the first embodiment.

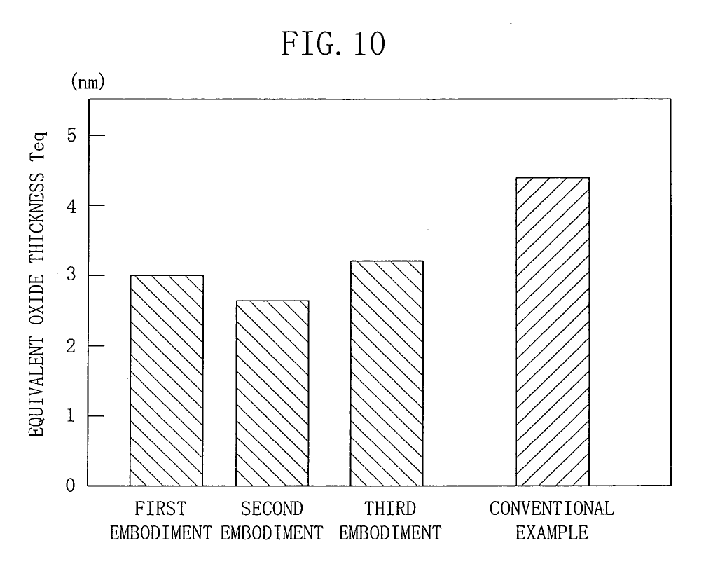

FIG. 10 shows equivalent oxide thicknesses of capacitive insulating films included in capacitors obtained by the first through third embodiments and the conventional example, respectively. In FIG. 10, the equivalent oxide thickness (T_{eq}) is the thickness of a capacitive insulating film calculated from the capacitance obtained by measurement. The thickness is calculated by assigning, to the dielectric constant, 3.9 which is the dielectric constant of a silicon dioxide (SiO₂) film. That is, the equivalent oxide thickness is an index of the thickness required to obtain the same capacitance value by using a silicon dioxide film. The equivalent oxide thickness decreases as the dielectric constant of a capacitive insulating film including an interface layer increases. In FIG. 10, the thicknesses of the capacitive insulating films of tantalum oxide in the conventional example and the embodiments are 10 nm. As shown in FIG. 10, the equivalent oxide thickness in the second embodiment is smallest and the equivalent oxide thickness in the third embodiment is slightly larger than that in the first embodiment. The equivalent oxide thickness in the conventional example is larger than the other thicknesses. This is because in the conventional example, an oxidant penetrates the silicon thermal nitride film 108a as an interface layer of the capacitive insulating film 109 during annealing using ozone so that the silicon oxide film 108b is formed under the silicon thermal nitride film 108a.

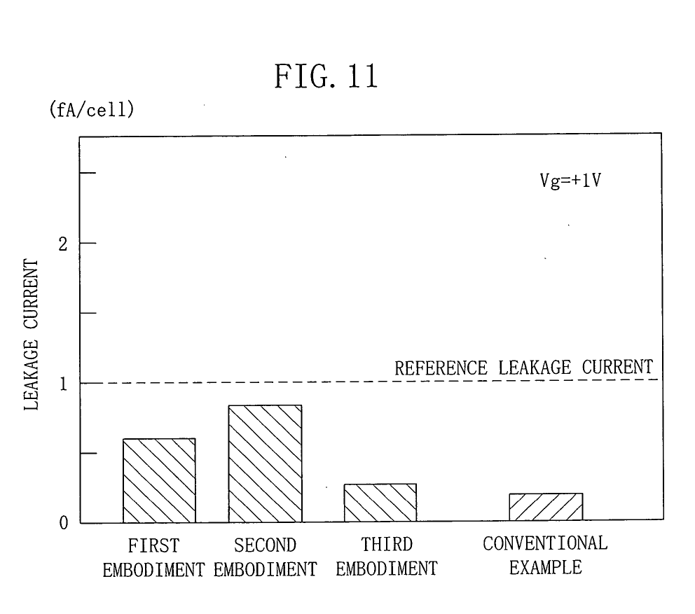

FIG. 11 shows values of leakage current in capacitive insulating films included in capacitors obtained by the first through third embodiments and the conventional example, respectively. The value of leakage current flowing in a capacitive insulating film decreases as the thickness of the capacitive insulating film increases. As shown in FIG. 11, the leakage current value is smallest in the conventional example and increases in the order of the third, first and second embodiments. The result shown in FIG. 11 is obvious from the equivalent oxide thicknesses shown in FIG. 10. This is because it is not always the case that the smaller the leakage current value in a capacitor the better, in general. There arise no problems as long as the leakage current value is equal to or smaller than a reference value. FIG. 11 shows a reference leakage current value (1 fA/cell). If the leakage current value is smaller than the reference leakage current value, the result obtained from the equivalent oxide thickness is more important.

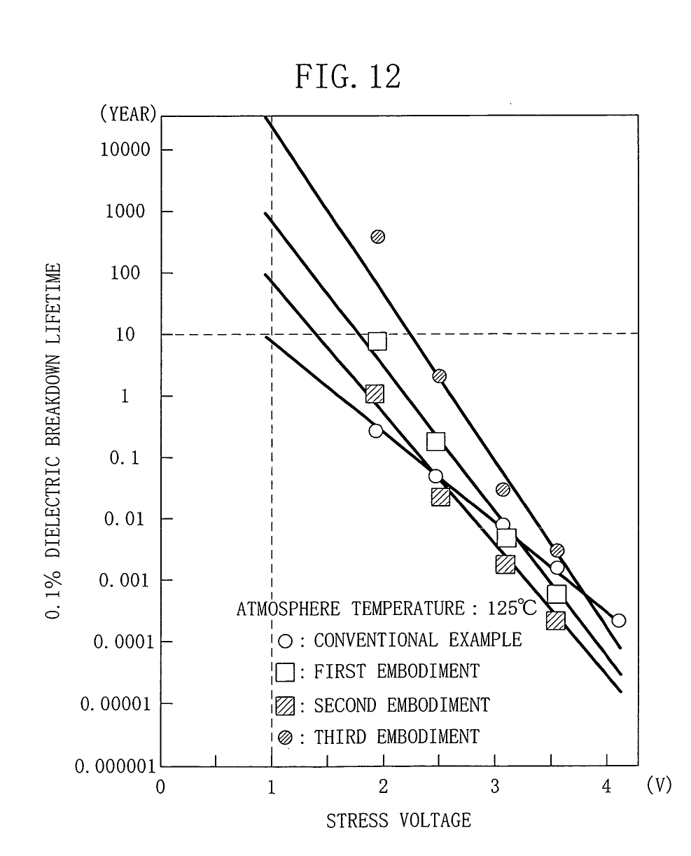

FIG. 12 shows estimated values of 0.1% dielectric breakdown lifetimes (i.e., lifetimes before dielectric breakdown occurs in 0.1% of capacitors subjected to a 125° C. atmosphere) in capacitors obtained by the first through third embodiments and the conventional example, respectively. As shown in FIG. 12, the dielectric breakdown lifetime decreases in the order of the third embodiment, the first embodiment, the second embodiment and the conventional example.

### Embodiment 4

Hereinafter, a fourth embodiment of the present invention will be described with reference to the drawings.

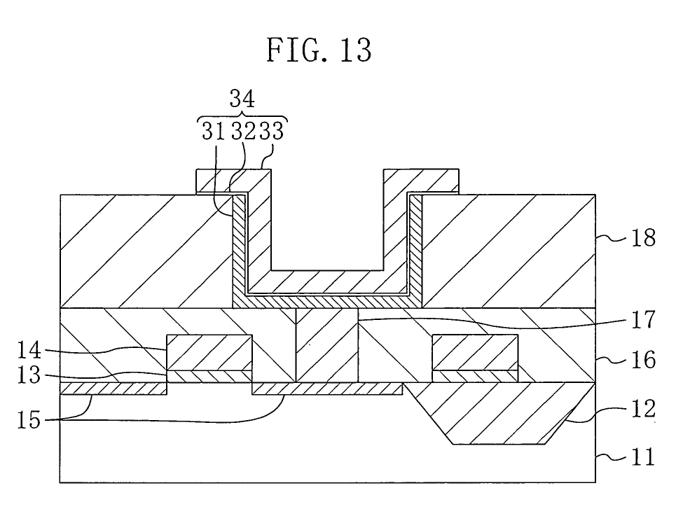

FIG. 13 shows a cross-sectional structure of a main portion of a semiconductor device including a capacitor according to the fourth embodiment. In FIG. 13, components also shown in FIG. 1 are denoted by the same reference numerals, and the description thereof will be omitted.

As shown in FIG. 13, a capacitor 34 according to the fourth embodiment is formed on the bottom and inner wall of an opening formed in a second interlayer dielectric film 18 and includes a lower electrode 31 of titanium nitride (TiN) serving as a storage node connected to one of source/drain regions 15 for an access transistor. A capacitive insulating film 32 of tantalum oxide having a thickness of about 6 nm and an upper electrode 33 of titanium nitride having a thickness of about 20 nm are formed in this order over the lower electrode 31, thereby forming a so-called MIM capacitor.

Instead of titanium nitride, tantalum nitride or tungsten nitride may be used for the lower electrode 31 and upper electrode 33. Instead of tantalum oxide, hafnium oxide may be used for the capacitive insulating film 32.

Hereinafter, a method for forming a capacitor of a semiconductor device thus configured will be described with reference to the drawings.

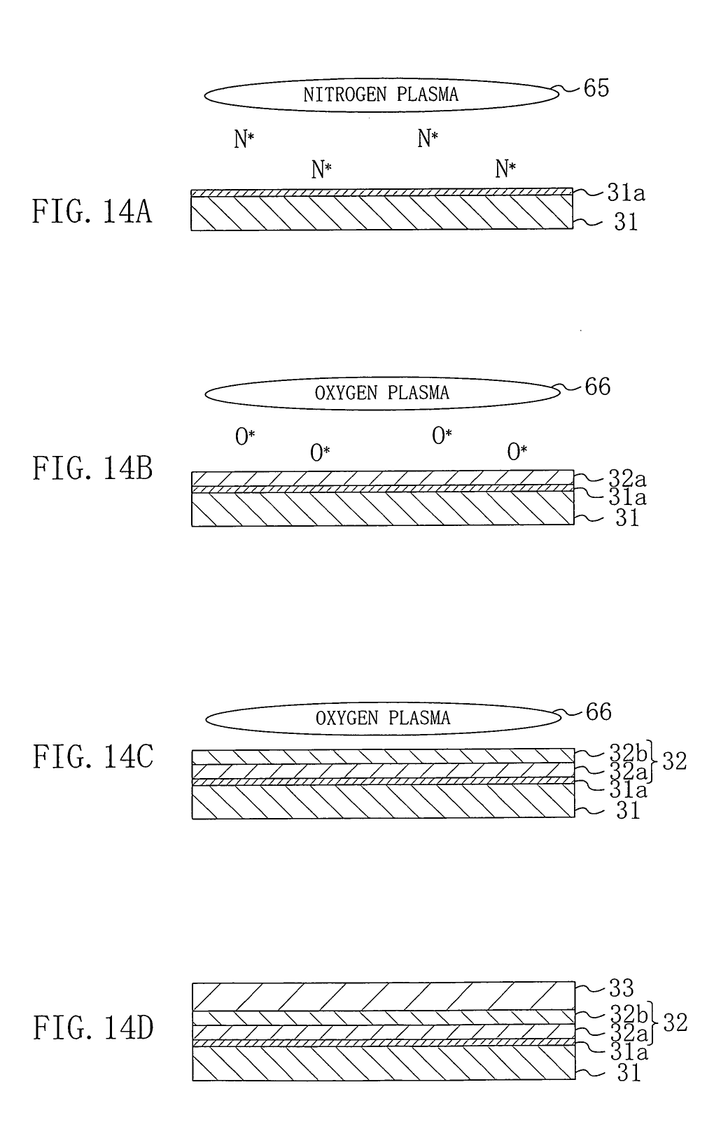

FIGS. 14A through 14D show a method for forming the capacitor of the semiconductor device according to the fourth embodiment. In the drawings, parts of the cross-sectional structures of the capacitor in respective process steps are shown in an enlarged manner.

First, with an atomic layer deposition (ALD) process, for example, material gases of titanium tetrachloride (TiCl₄) as a titanium source and ammonia (NH₃) as a nitrogen source are alternately introduced at 450° C. onto the bottom and inner wall of an opening formed in a second interlayer dielectric film 18. In this manner, a lower electrode 31 of titanium nitride with a thickness of about 20 nm in the shape of a cylinder having a bottom is formed on the bottom and inner wall of the opening in the second interlayer dielectric film 18.

Next, as shown in FIG. 14A, nitrogen plasma 65 with an electron energy of about 1 eV is generated by using a magnetron at a substrate temperature of 400° C., an output of about 250 W, a nitrogen-gas flow rate of about 300 ml/min (0° C./1 atm) and a pressure of about 30 Pa. Then, the lower electrode 31 is subjected to the nitrogen plasma 65 for 10 seconds. In this manner, a nitrogen-rich layer 31a to which nitrogen has been introduced is formed in the surface and its neighboring part of the lower electrode 31. This nitrogen-rich layer 31a has its surface state stabilized as compared to the state before the introduction of nitrogen. Accordingly, the surface of the nitrogen-rich layer 31a is not oxidized even when a capacitive insulating film 32 of tantalum oxide is formed in a subsequent process.

Then, as shown in FIG. 14B, over the lower electrode 31 in which the nitrogen-rich layer 31a has been formed, a first capacitive insulating film 32a of tantalum oxide (TaOₓ) is deposited to a thickness of about 3 nm by a MOCVD process at a temperature of about 400° C. and a pressure of about 30 Pa with tantalum ethoxide (Ta(OC₂H₅)₅) as a tantalum source and oxygen (O₂) mixed. Subsequently, oxygen plasma 66 with an electron energy of about 1 eV is generated at a temperature of about 400° C., a magnetron output of about 300 W, an oxygen-gas flow rate of about 25 ml/min (0° C., 1 atm), a krypton (Kr)-gas flow rate of about 375 nm/min (0° C., 1 atm) and a pressure of about 30 Pa. Then, the first capacitive insulating film 32a is subjected for 70 seconds to oxygen radicals O* generated from the oxygen plasma 66. In this manner, oxygen is supplied to tantalum oxide constituting the first capacitive insulating film 32a so as to compensate for oxygen deficiency and organic carbon contained in this tantalum oxide is removed. The oxygen radicals O* with a low electron energy of about 1 eV reach a depth as small as about 3 nm from the surface of the tantalum oxide. Accordingly, the thickness of the first capacitive insulating film 32a is set at about 3 nm in this embodiment, so that a sufficient amount of oxygen is supplied to the first capacitive insulating film 32a and, in addition, the nitrogen-rich layer 31a, as an interface layer between the lower electrode 31 and the first capacitive insulating film 32a, and the lower electrode 31 are not oxidized.

In the conventional example, oxygen is supplied to the capacitive insulating film using ozone and oxygen plasma. However, as described above, ozone is very active and therefore oxidizes even the lower electrode as an underlying layer. In addition, general oxygen plasma processing has high energy, so that ions reach even the lower electrode so that the lower electrode is oxidized.

In the fourth embodiment, the first capacitive insulating film 32a of tantalum oxide is oxidized by using oxygen radicals with a low energy of about 1 eV. Accordingly, oxygen is supplied to tantalum oxide efficiently, and oxygen radicals do not reach the lower electrode 31 below 3 nm from the surface so that the lower electrode 31 is not oxidized. In addition, before the first capacitive insulating film 32a is deposited, the lower electrode 31 is subjected to the nitrogen plasma 65 and thereby the nitrogen-rich layer 31a is formed in the surface of the lower electrode 31. Accordingly, oxidation is also suppressed by the nitrogen-rich layer 31a.

Thereafter, as shown in FIG. 14C, a second capacitive insulating film 32b of tantalum oxide is deposited by an MOCVD process to a thickness of about 3 nm over the first capacitive insulating film 32a, under the same conditions as those for the first capacitive insulating film 32a. Subsequently, the second capacitive insulating film 32b is subjected for 60 seconds to oxygen plasma 66 generated under the same conditions as those for the first process, thereby supplying oxygen to the second capacitive insulating film 32b and removing organic carbon contained therein. In this manner, a capacitive insulating film 32 in which the first capacitive insulating film 32a and the second capacitive insulating film 32b are stacked.

To generate the low-energy nitrogen plasma 65 and oxygen plasma 66, a magnetron is not necessarily used. It is sufficient to use a plasma source with high plasma density (>1×10¹⁰/cm²) and low energy (0.5 eV to 5 eV) such as inductively coupled plasma, surface-wave plasma or helicon-wave plasma.

In the fourth embodiment, oxygen supply using oxygen plasma 66 is performed at 400° C. However, the present invention is not limited to this, and substantially the same advantages are obtained even if oxygen supply is performed at room temperature. In the fourth embodiment, since the capacitive insulating films 32a and 32b are deposited at 400° C., the oxygen supply is also performed at the same temperature, i.e., 400° C. As described above, under this temperature, tantalum oxide after deposition is amorphous, and both the leakage current characteristic and the dielectric constant do not exhibit sufficient values. However, in an integrated circuit which needs an MIM capacitor 34 including a capacitive insulating film 32 of a metal oxide formed on a lower electrode 31 of a metal or a metal nitride, thermal budget needs to be reduced as much as possible, and therefore thermal processing on the capacitor 34 is required to be performed at 500° C. or lower. For this reason, the capacitive insulating film 32 is used in an amorphous state.

Then, in a process step shown in FIG. 14D, instead of a CVD process with a deposition temperature exceeding 500° C., an ALD process in which alternate introduction of titanium tetrachloride and ammonia onto the capacitive insulating film 32 is repeated under 400° C. until the thickness of the resultant film reaches a given value is used, and an upper electrode 33 of titanium nitride is deposited to a thickness of 20 nm as an upper cell plate electrode.

In the fourth embodiment, in the case of an integrated circuit having a margin for its thermal budget, thermal processing may be performed at 700° C. in a nitrogen atmosphere for about one minute with rapid thermal processing (RTP) apparatus after the formation of the upper electrode 33. Then, tantalum oxide constituting the upper electrode 33 is crystallized, thus reducing leakage current and increasing the dielectric constant.

As described above, the method for fabricating a semiconductor device according to the present invention allows control of the thickness of an interface layer formed at the interface between a lower electrode and a capacitive insulating film and also ensures oxygen supply to the capacitive insulating film of a metal oxide in which oxygen deficiency occurs immediately after the formation thereof. Accordingly, a capacitor with high capacitance, low leakage characteristic and high reliability is implemented. A capacitor formed by the method of the present invention is effective as a capacitor with an MIS or MIM structure, and is effective especially for a semiconductor device or others including a capacitor constituting a memory cell.

1. A method for fabricating a semiconductor device, the method comprising the steps of:
(a) subjecting a first electrode made of polycrystalline silicon to first plasma containing oxygen, thereby forming a silicon oxide film in the surface of the first electrode;
(b) subjecting the first electrode in which the silicon oxide film has been formed to second plasma containing nitrogen, thereby changing the silicon oxide film into a silicon oxynitride film;
(c) forming a capacitive insulating film made of a metal oxide on the first electrode in which the silicon oxynitride film has been formed;
(d) subjecting the capacitive insulating film to third plasma containing oxygen, thereby supplying oxygen to the capacitive insulating film;
(e) performing thermal processing in an oxidizing atmosphere on the capacitive insulating film to which oxygen has been supplied; and
(f) forming a second electrode on the capacitive insulating film.

2. The method of claim 1, wherein each of the first, second and third plasma has an electron energy between 0.5 eV and 5 eV, both inclusive, and is generated at a temperature between room temperature and 500° C., both inclusive.

3. The method of claim 1, wherein each of the first and third plasma is generated from oxygen gas or mixed gas obtained by adding krypton to oxygen.

4. The method of claim 1, wherein the second plasma is generated from nitrogen gas or mixed gas obtained by adding helium or argon to nitrogen.

5. The method of claim 1, wherein the silicon oxide film formed in the surface of the first electrode has a thickness between 1 nm and 4 mm, both inclusive.

6. The method of claim 1, wherein a series of processes in which part of the capacitive insulating film is formed in step (c) and then step (d) is performed is repeated until the thickness of the capacitive insulating film reaches a given value.

7. The method of claim 6, wherein the capacitive insulating film obtained by said series of processes has an initial thickness between 2 nm and 4 run, both inclusive.

8. The method of claim 1, further comprising the step of making the surface of the first electrode uneven before step (a) is performed.

9. The method of claim 1, wherein the second electrode is made of titanium nitride, tantalum nitride or tungsten nitride.

10. The method of claim 1, wherein the capacitive insulating film contains tantalum oxide or hafnium oxide as a main component.

11. The method of claim 1, wherein the oxidizing atmosphere in the thermal processing performed on the capacitive insulating film contains dinitrogen monoxide.

12. A method for fabricating a semiconductor device, the method comprising the steps of:
(a) subjecting a first electrode made of polycrystalline silicon to first plasma containing nitrogen, thereby forming a silicon nitride film in the surface of the first electrode;
(b) forming a capacitive insulating film made of a metal oxide on the first electrode in which the silicon nitride film has been formed;
(c) subjecting the capacitive insulating film to second plasma containing oxygen, thereby supplying oxygen to the capacitive insulating film;
(d) performing thermal processing in an oxidizing atmosphere on the capacitive insulating film to which oxygen has been supplied; and
(e) forming a second electrode on the capacitive insulating film.

13. The method of claim 12, wherein each of the first and second plasma has an electron energy between 0.5 eV and 5 eV, both inclusive, and is generated at a temperature between room temperature and 500° C., both inclusive.

14. The method of claim 12, wherein the first plasma is generated from nitrogen gas or mixed gas obtained by adding helium or argon to nitrogen.

15. The method of claim 12, wherein the second plasma is generated from oxygen gas or mixed gas obtained by adding krypton to oxygen.

16. The method of claim 12, further comprising the step of performing thermal processing on the first electrode in an atmosphere containing nitrogen atoms, thereby forming a silicon thermal nitride film in the surface of the first electrode before step (a) is performed,
wherein the silicon nitride film into which the silicon thermal nitride film has been changed is obtained in step (a).

17. The method of claim 12, wherein after part of the capacitive insulating film has been formed in step (b), a series of processes for implementing step (c) is repeated until the thickness of the capacitive insulating film reaches a given value.

18. The method of claim 17, wherein the capacitive insulating film obtained by said series of processes has an initial thickness between 2 nm and 4 nm, both inclusive.

19. The method of claim 12, further comprising the step of making the surface of the first electrode uneven before step (a) is performed.

20. The method of claim 12, wherein the second electrode is made of titanium nitride, tantalum nitride or tungsten nitride.

21. The method of claim 12, wherein the capacitive insulating film contains tantalum oxide or hafnium oxide as a main component.

22. The method of claim 12, wherein the oxidizing atmosphere in the thermal processing performed on the capacitive insulating film contains dinitrogen monoxide.

23. A method for fabricating a semiconductor device, the method comprising the steps of:
(a) forming an insulating interface layer in the surface of a first electrode made of polycrystalline silicon;
(b) forming part of a capacitive insulating film made of a metal oxide on the first electrode in which the interface layer has been formed;
(c) subjecting said part of the capacitive insulating film to plasma containing oxygen, thereby supplying oxygen to said part of the capacitive insulating film;
(d) repeating steps (b) and (c) as a series of processes until the thickness of the capacitive insulating film reaches a given value, and then performing thermal processing on the capacitive insulating film with said given thickness in an oxidizing atmosphere; and
(e) forming a second electrode on the capacitive insulating film.

24. The method of claim 23, wherein the plasma has an electron energy between 0.5 eV and 5 eV, both inclusive, and is generated at a temperature between room temperature and 500° C., both inclusive.

25. The method of claim 23, wherein the plasma is generated from oxygen gas or mixed gas obtained by adding krypton to oxygen.

26. The method of claim 23, wherein in step (a), the first electrode is subjected to plasma containing oxygen with an electron energy between 0.5 eV and 5 eV, both inclusive, at a temperature between room temperature and 500° C., both inclusive, thereby forming the interface layer as a silicon oxide film.

27. The method of claim 23, wherein in step (a), the first electrode is subjected to plasma containing nitrogen with an electron energy between 0.5 eV and 5 eV, both inclusive, at a temperature between room temperature and 500° C., both inclusive, thereby forming the interface layer as a silicon nitride film.

28. The method of claim 23, wherein the capacitive insulating film obtained by said series of processes has an initial thickness between 2 nm and 4 nm, both inclusive.

29. The method of claim 23, further comprising the step of making the surface of the first electrode uneven before step (a) is performed.

30. The method of claim 23, wherein the second electrode is made of titanium nitride, tantalum nitride or tungsten nitride.

31. The method of claim 23, wherein the capacitive insulating film contains tantalum oxide or hafnium oxide as a main component.

32. The method of claim 23, wherein the oxidizing atmosphere in the thermal processing performed on the capacitive insulating film contains dinitrogen monoxide.

33. A method for fabricating a semiconductor device, the method comprising the steps of:
(a) subjecting a conductive first electrode made of a metal nitride to first plasma containing nitrogen, thereby forming a nitrogen-rich layer in the surface of the first electrode, the nitrogen-rich layer having a nitrogen content greater than that in the other part of the first electrode;
(b) forming a capacitive insulating film made of a metal oxide on the first electrode in which the nitrogen-rich layer has been formed;
(c) subjecting the capacitive insulating film to second plasma containing oxygen, thereby supplying oxygen to the capacitive insulating film; and
(d) forming a second electrode on the capacitive insulating film.

34. The method of claim 33, wherein each of the first and second plasma has an electron energy between 0.5 eV and 5 eV, both inclusive, and is generated at a temperature between room temperature and 500° C., both inclusive.

35. The method of claim 33, wherein the first plasma is generated from nitrogen gas or mixed gas obtained by adding helium or argon to nitrogen.

36. The method of claim 33, wherein the second plasma is generated from oxygen gas or mixed gas obtained by adding krypton to oxygen.

37. The method of claim 33, wherein part of the capacitive insulating film is formed in step (b), and then a series of processes for implementing step (c) is repeated until the thickness of the capacitive insulating film reaches a given value.

38. The method of claim 33, wherein the first electrode is made of titanium nitride, tantalum nitride or tungsten nitride.

39. The method of claim 33, wherein the second electrode is made of titanium nitride, tantalum nitride or tungsten nitride.

40. The method of claim 33, wherein the capacitive insulating film contains tantalum oxide or hafnium oxide as a main component.

41. The method of claim 33, wherein the oxidizing atmosphere in the thermal processing performed on the capacitive insulating film contains dinitrogen monoxide.
